(19) United States
(12) Patent Application Publication
(10) Pub. No.: US 2011/0175681 A1
(43) Pub. Date: Jul. 21, 2011

(54) RADIO FREQUENCY POWER AMPLIFIER AND WIRELESS COMMUNICATION DEVICE INCLUDING THE SAME

(75) Inventors: Masahiko INAMORI, Osaka (JP); Kaname MOTOYOSHI, Hyogo (JP); Masao NAKAYAMA, Shiga (JP); Kouki YAMAMOTO, Shiga (JP); Tsunehiro TAKAGI, Kyoto (JP); Hiroshi SUGIYAMA, Osaka (JP); Junji KAIDO, Osaka (JP)

(73) Assignee: PANASONIC CORPORATION, Osaka (JP)

(21) Appl. No.: 12/971,452

(22) Filed: Dec. 17, 2010

(30) Foreign Application Priority Data
Jan. 21, 2010 (JP) 2010-010804
Nov. 15, 2010 (JP) 2010-255388

(51) Int. Cl. H03F 3/04

(52) U.S. Cl. 330/296

(57) ABSTRACT

To provide a radio frequency power amplifier that realizes a favorable high-frequency characteristic without using an isolator and also achieves low power consumption. The radio frequency power amplifier includes: a power amplifier which amplifies a radio frequency signal; a voltage supplying unit which supplies a collector voltage to the power amplifier; a current supplying unit which supplies a bias current to the power amplifier; and a bias current detecting unit which detects the bias current. The voltage supplying unit has a control unit which sets the power supply voltage at: a first voltage when the detected bias current is lower than a bias-current reference value; and a second voltage lower than the first voltage when the detected bias current is higher than the bias-current reference value.

### BACKGROUND OF THE INVENTION

(1) Field of the Invention

The present invention relates to a radio frequency power amplifier which amplifies power of a radio frequency signal, and particularly relates to a radio frequency power amplifier which addresses changes in output load and to a wireless communication device having such a radio frequency power amplifier.

(2) Description of the Related Art

In recent years, there has been a rapid proliferation of mobile phone terminals that support multiple frequency bands and multimode systems to allow for global use. The multiple frequency bands include, for example, bands with center frequencies of 2 GHz and 900 MHz. In a multimode system, Global System for Mobile Communications (GSM), Digital Communication System (DCS), Universal Mobile Telecommunications System (UMTS), and the like are possible. This proliferation has resulted in an increasing need for miniaturization, enhanced performance, and reduced cost of transmission power amplifiers performing high power amplification in the mobile phone terminals.

Generally speaking, metal objects, walls, or human bodies near an antenna of a mobile phone terminal can cause changes in output load impedance of a power amplifier performing high power amplification. There may be a case where the output load impedance is substantially different from a design value of 50Ω. In such a case, the output power, distortion characteristic, and current consumption of the power amplifier are changed, thereby degrading the quality of phone communication. In order to avoid this, an isolator capable of absorbing changes in antenna impedance is inserted between the power amplifier and the antenna.

The isolator insertion can stabilize the changes in the output load impedance of the power amplifier. However, a large footprint of 2×2 mm² per isolator presents a barrier to miniaturization of the mobile phone terminal. Moreover, the insertion loss of the isolator is about 0.5 dB, which accordingly increases the power consumption by the power amplifier. In addition, a multiband power amplifier needs as many isolators as the number of bands, which inevitably leads to high cost.

To address this problem, there are various efforts underway to create power amplifiers that require no isolator.

FIG. 21 is a block diagram showing a configuration of a conventional radio frequency power amplifier with no isolator in Patent Reference 1 (Japanese Unexamined Patent Application Publication No. 2003-338714).

In a radio frequency power amplifier 900 disclosed in Patent Reference 1 and shown in FIG. 21, an amplifier 901 amplifies a radio frequency signal received by an input terminal 910. A signal Va corresponding to the power of a traveling wave is extracted from a traveling-wave directional coupler 902, and also a signal Vb corresponding to the power of a reflected wave is extracted from a reflected-wave directional coupler 903. The traveling-wave directional coupler 902 and the reflected-wave directional coupler 903 are connected between an output of the amplifier 901 and an antenna 907. Based on the signal Va corresponding to the power of the traveling wave and the signal Vb corresponding to the power of the reflected wave, an arithmetic circuit 904 calculates a power supply voltage Vdd to be supplied to the amplifier 901. Then, a DC-DC converter 905 supplies, to the amplifier 901, the power supply voltage Vdd obtained as a result of the calculation.

In this way, in the radio frequency power amplifier 900, the reflected-wave directional coupler 903 detects the power of the reflected wave caused by the antenna 907 due to the antenna impedance, and the DC-DC converter 905 accordingly controls the power supply voltage Vdd. As a result, the distortion characteristic is prevented from degrading. The radio frequency power amplifier 900 further includes a supply current monitor circuit 906 that monitors a power supply current supplied to the amplifier 901. With this, an increase in power consumption is prevented by reducing the power supply voltage Vdd in a load area where the power supply current supplied to the amplifier 901 is high.

Moreover, Patent Reference 2 (Japanese Unexamined Patent Application Publication No. 2008-66867) discloses a configuration in which a directional coupler detects the amplitude and phase of antenna reflected power caused due to antenna impedance, and a DC-DC converter controls a power supply voltage according to the detected amplitude and phase. Accordingly, the configuration disclosed in Patent Reference 2 reduces the degradation in the distortion characteristic and prevents an increase in power consumption.

As described above, each of the configurations disclosed in Patent References 1 and 2 implements a radio frequency power amplifier that reduces the degradation in the distortion characteristic without using an isolator and also prevents an increase in power consumption.

### SUMMARY OF THE INVENTION

However, the configurations disclosed in Patent References 1 and 2 have the following problems.

As a first problem in the configurations disclosed in Patent References 1 and 2, the directional couplers need to be provided to detect the antenna reflected power. This means that a power loss is caused by these directional couplers.

To be more specific, since the directional couplers are set on an output signal line of the power amplifier, a further insertion loss of at least about 0.5 dB is caused in addition to the insertion loss of about 0.2 dB caused by the reflected-power detection. The reasons for this further loss includes a loss due to a mismatch between the directional couplers and the load circuit of the power amplifier, and a loss due to a coupling with a lack of isolation between the directional couplers and the output load circuit of the power amplifier since they are next to each other when a detection signal line is laid out on the mobile phone terminal. In other words, the power amplifier included in the radio frequency power amplifier having the directional couplers for detecting the reflected power without using an isolator needs to raise the output power to at least about 0.7 dB which is higher than the isolator insertion loss of about 0.5 dB. That is to say, even when the load impedance is 50Ω (i.e., the design value), the power consumption may increase as compared to the case where an isolator is used.

Such an increase in power consumption caused even when the load impedance is at the design value may reduce the length of talk time on the mobile phone and may cause a heat problem or the like.

Moreover, a second problem is a power loss caused by monitoring the current supplied to the power amplifier.

To be more specific, in the configuration disclosed in Patent Reference 1, the supply current monitor circuit monitors the power supply current, so as to reduce the power supply voltage in the load area where the power supply current is high. However, when a high current, which refers to a power supply current flowing when the output power is high, is detected using a monitor resistance, an enormous amount of power is consumed by the supply current monitor circuit. The current monitored by the supply current monitor circuit is, for example, from hundreds of milliamperes to amperes. On this account, even when a resistance with a small resistance value is used as a supply current monitor circuit, this supply current monitor circuit consumes a large amount of power.

Thus, with consideration given to the power consumption by the supply current monitor circuit and to the power loss by the directional couplers, the power consumption is larger than in the case where an isolator is used.

As can be understood from the above, the configurations disclosed in Patent References 1 and 2 increase the actual power consumption as compared to the case where an isolator is used.

In view of the stated problems, the present invention has an object to provide: a radio frequency power amplifier which realizes a favorable high frequency characteristic without using an isolator and also achieves low power consumption; and a wireless communication device having such a radio frequency power amplifier.

In order to achieve the aforementioned object, the radio frequency power amplifier according to an aspect of the present invention is a radio frequency power amplifier including: an amplifying unit which amplifies a radio frequency signal; a voltage supplying unit which supplies a power supply voltage to the amplifying unit; a current supplying unit which supplies a bias current to the amplifying unit; and a detecting unit which detects the bias current, wherein the voltage supplying unit includes a control unit which sets the power supply voltage at: a first voltage when a value of the detected bias current is equal to or lower than a threshold; and a second voltage lower than the first voltage when the value of the detected bias current is higher than the threshold.

With this, a favorable high frequency characteristic can be achieved without using an isolator, and the power consumption can be reduced.

Also, the threshold may indicate a bias-current reference value in association with a value of an output power of the amplifying unit, the bias-current reference value corresponding to an ideal output load on the radio frequency power amplifier.

Moreover, the radio frequency power amplifier may further include: a memory which stores a plurality of bias-current reference values in association with a plurality of values of the output power, the bias-current reference values corresponding to the ideal output load on the radio frequency power amplifier; and an obtaining unit which obtains the value of the output power of the amplifying unit, wherein the control unit compares the bias-current reference value stored in the memory in association with the obtained value of the output power of the amplifying unit and the value of the bias current detected by the detecting unit, and sets the power supply voltage at: the first voltage when the value of the bias current detected by the detecting unit is equal to or lower than the bias-current reference value stored in the memory; and the second voltage when the value of the bias current detected by the detecting unit is higher than the bias-current reference value stored in the memory.

Furthermore, the second voltage may be a voltage for causing an adjacent channel leakage ratio of the radio frequency power amplifier to be lower than a predetermined value when the value of the detected bias current is higher than the threshold.

With this, the specifications based on the laws and regulations, such as the Radio Act, can be satisfied and the power consumption can be reduced at the same time. In other words, unnecessary radiation can be prevented and the power consumption can thus be reduced.

Also, the first voltage may be a voltage for causing the adjacent channel leakage ratio of the radio frequency power amplifier to be lower than the predetermined value regardless of the value of the detected bias current.

With this, the specifications based on the laws and regulations, such as the Radio Act, can always be satisfied. This is to say, unnecessary radiation can be reliably prevented in any load condition.

Moreover, when the power supply voltage is set at the first voltage and the value of the detected bias current becomes higher than the threshold, the control unit may change the power supply voltage from the first voltage to the second voltage.

With this, even when the load impedance changes during communication, the radio frequency power amplifier can reduce the power consumption.

Furthermore, when the power supply voltage is set at the second voltage and the value of the detected bias current becomes equal to or lower than the threshold, the control unit may change the power supply voltage from the second voltage to the first voltage.

With this, even when the load impedance changes during communication, the radio frequency power amplifier can achieve a favorable distortion characteristic.

Also, the control unit may further control the power supply voltage according to the output power of the amplifying unit.

Moreover, when the output power of the amplifying unit is higher than a predetermined power, the control unit may set a first upper-limit voltage as the first voltage, and when the output power of the amplifying unit is equal to or lower than the predetermined power, the control unit may set, as the first voltage, a second upper-limit voltage lower than the first upper-limit voltage.

Furthermore, when the output power of the amplifying unit is higher than the predetermined power, the control unit may set a voltage equal to or higher than the second upper-limit voltage as the second voltage.

Also, the obtaining unit may be connected to the amplifying unit and may detect the output power of the amplifying unit.

Moreover, the amplifying unit may have: a first amplifying element which amplifies the radio frequency signal in a first frequency band; a second amplifying element which amplifies the radio frequency signal in a second frequency band different from the first frequency band; and a bias line provided in common to the first amplifying element and the second amplifying element so that the bias current is supplied to each of the first amplifying element and the second amplifying element.

This can accordingly support the multiple bands. Also, a single bias current detecting unit is used for detecting the bias currents, thereby realizing miniaturization.

Furthermore, each of the first amplifying element and the second amplifying element may be a transistor, the amplifying unit may further have: a first line connected to a collector of the first amplifying element and used for transmitting the radio frequency signal amplified by the first amplifying element; a second line connected to an emitter of the first amplifying element; a third line connected to a collector of the second amplifying element and used for transmitting the radio frequency signal amplified by the second amplifying element; and a fourth line connected to an emitter of the second amplifying element, and the bias line is arranged so as not to overlap with any of the first to fourth lines.

This can reduce the influence of signal leakage from an active amplifying element (one of the first amplifying element and the second amplifying element) to an inactive amplifying element (the other one of the first amplifying element and the second amplifying element) via the first to fourth lines and the bias line. To be more specific, in the multiband power amplifier, while one of the first amplifying element and the second amplifying element is active, the other one is inactive. When the radio frequency signal having been amplified by the active amplifying element is leaked out to the inactive amplifying element via the bias line, a malfunction or a reduction in transmission output may occur as a result. By arranging the bias line so as not to overlap with any of the first to fourth lines, a leakage of the radio frequency signal via the bias line is prevented. Thus, a malfunction or a reduction in transmission output is prevented from occurring to the amplifying unit.

Also, the amplifying unit may have: an m number of amplifying elements connected in multiple stages, m being an integer of at least 2; and an m number of bias lines for supplying bias currents to the m number of amplifying elements, respectively, and the detecting unit may detect the bias current supplied to at least one of the m number of bias lines.

With this, as compared to the case where the amplifying unit is configured by a single amplifying element, the amplifier gain can be increased. Such a radio frequency power amplifier is suitable for a power amplifier (PA) for transmission, for example.

Moreover, the detecting unit may detect the bias current supplied to a bias line corresponding to an amplifying element of a final stage out of the multiple stages.

Accordingly, without being influenced by the changes in the bias current of the amplifying element which is phase-shifted from the amplifying element in the final stage, the detecting unit is influenced only by the changes in the bias current of the amplifying element of the final stage. In other words, the influence of the bias current of the amplifying element of a stage other than the final stage can be excluded from the bias current detected by the detecting unit. As a result, the detecting unit can precisely detect the bias current of the amplifying element of the final stage, thereby improving the distortion characteristic of the radio frequency power amplifier.

To be more specific, the distortion characteristic of the amplifying unit including the multistage-connected amplifying elements is dominantly influenced by the amplifying element of the final stage. On this account, the detecting unit detects the bias current of the amplifying element of the final stage with a high degree of precision while excluding the influence of the bias current of the amplifying element of the stage other than the final stage. Then, according to the bias current detected with a high degree of precision, the collector voltage is controlled. This accordingly results in an improvement in the distortion characteristic.

Furthermore, the detecting unit may detect the bias currents supplied to the m number of bias lines, in association with the m number of amplifying elements, respectively.

With this, even in the event of a phase shift between the stages or degradation in the distortion characteristic of the amplifying element of one of the stages, the power supply voltage can be controlled with consideration given to the influence caused by the event

Also, the control unit may further control the power supply voltage, according to a difference between: the bias current supplied to an amplifying element, out of the m number of amplifying elements, of an i-th stage where 1≦m-1; and the bias current supplied to an amplifying element, out of the m number of amplifying elements, of a j-th stage where i<j and 2≦j≦m.

With this, a destruction phase can be determined when the load changes, so that destruction can be avoided. To be more specific, a phase in which destruction is to occur includes a current-falling edge in the current phase transition. However, when the bias current of only one amplifying element is to be detected, both phases in which the current rises and falls are detected. Thus, destruction cannot be prevented. To address this, on the basis of a phase shift between the bias currents of the amplifying elements, a phase in which the bias current rises is determined. As a result of this, a phase in which destruction is to occur can be determined, thereby preventing the amplifying element from being destructed.

Moreover, the radio frequency power amplifier may further include: a current control transistor for controlling the bias current; and a temperature compensation circuit for performing temperature compensation on the current control transistor and the amplifying unit.

With this, in accordance with an external environment of the radio frequency power amplifier, the power supply voltage can be appropriately controlled.

The present invention can be implemented not only as the radio frequency power amplifier, but also as a wireless communication device having such a radio frequency power amplifier.

The present invention can implement a radio frequency power amplifier that realizes a favorable high frequency characteristic without using an isolator and that achieves low power consumption, and can also implement a wireless communication device having such a radio frequency power amplifier.

### FURTHER INFORMATION ABOUT TECHNICAL BACKGROUND TO THIS APPLICATION

The disclosure of Japanese Patent Application No. 2010-010804 filed on Jan. 21, 2010 including specification, drawings and claims is incorporated herein by reference in its entirety.

The disclosure of Japanese Patent Application No. 2010-255388 filed on Nov. 15, 2010 including specification, drawings and claims is incorporated herein by reference in its entirety.

### BRIEF DESCRIPTION OF THE DRAWINGS

These and other objects, advantages and features of the invention will become apparent from the following description thereof taken in conjunction with the accompanying drawings that illustrate a specific embodiment of the invention. In the Drawings:

FIG. 1 is a block diagram showing a configuration of a radio frequency power amplifier in a first embodiment.

FIG. 2 is a graph showing an example of data held by a memory unit.

FIG. 3 is a schematic circuit diagram showing a specific configuration of a power amplifier.

FIG. 4 is a schematic circuit diagram showing a specific configuration of a bias circuit of the power amplifier.

FIG. 5A is a graph showing a characteristic of an adjacent channel leakage ratio (ACLR) at 5-MHz offset when a collector voltage is 4 V.

FIG. 5B is a graph showing a collector current characteristic when the collector voltage is 4 V.

FIG. 6A is a graph showing a characteristic of the ACLR at 5-MHz offset when the collector voltage is 3 V.

FIG. 6B is a graph showing a collector current characteristic when the collector voltage is 3 V.

FIG. 7 is a graph showing a bias current characteristic when the collector voltage is 3.5 V.

FIG. 8 is a graph showing set values of the collector voltage, in association with the output power of the power amplifier.

FIG. 9 is a flowchart showing an operation performed by the radio frequency power amplifier.

FIG. 10 is a flowchart showing a specific process performed in a first process shown in FIG. 9.

FIG. 11 is a flowchart showing a specific process performed in a second process shown in FIG. 9.

FIG. 12 is a flowchart showing a specific process performed in a third process shown in FIG. 9.

FIG. 13 is a graph showing a characteristic of power consumption with respect to changes in load impedance of the radio frequency power amplifier.

FIG. 14 is a block diagram showing a configuration of a radio frequency power amplifier in a modification of the first embodiment.

FIG. 15 is a block diagram showing a configuration of a radio frequency power amplifier in a second embodiment.

FIG. 16 is a schematic circuit diagram showing a specific configuration of a power amplifier.

FIG. 17 is a block diagram showing a configuration of a radio frequency power amplifier in a third embodiment.

FIG. 18 is a schematic circuit diagram showing a specific configuration of a power amplifier.

FIG. 19 is a block diagram showing a configuration of a radio frequency power amplifier in a fourth embodiment.

FIG. 20 is a schematic circuit diagram showing a specific configuration of a power amplifier.

FIG. 21 is a diagram showing a configuration of a conventional radio frequency power amplifier with no isolator.

### DESCRIPTION OF THE PREFERRED EMBODIMENTS

The following is a description of a radio frequency power amplifier and a wireless communication device according to the present invention, based on embodiments and modifications. It should be noted that the same reference numerals are used to denote identical components, and that their explanations may not be repeated.

### First Embodiment

A radio frequency power amplifier in the first embodiment includes: an amplifying unit which amplifies a radio frequency signal; a voltage supplying unit which supplies a power supply voltage to the amplifying unit; a current supplying unit which supplies a bias current to the amplifying unit; and a detecting unit which detects the bias current. The voltage supplying unit has a control unit which sets the power supply voltage at: a first voltage when the detected bias current is equal to or lower than a threshold; and a second voltage lower than the first voltage when the detected bias current is higher than the threshold.

With this configuration, the radio frequency power amplifier in the present embodiment can achieve a favorable high frequency characteristic without using an isolator and can also reduce power consumption.

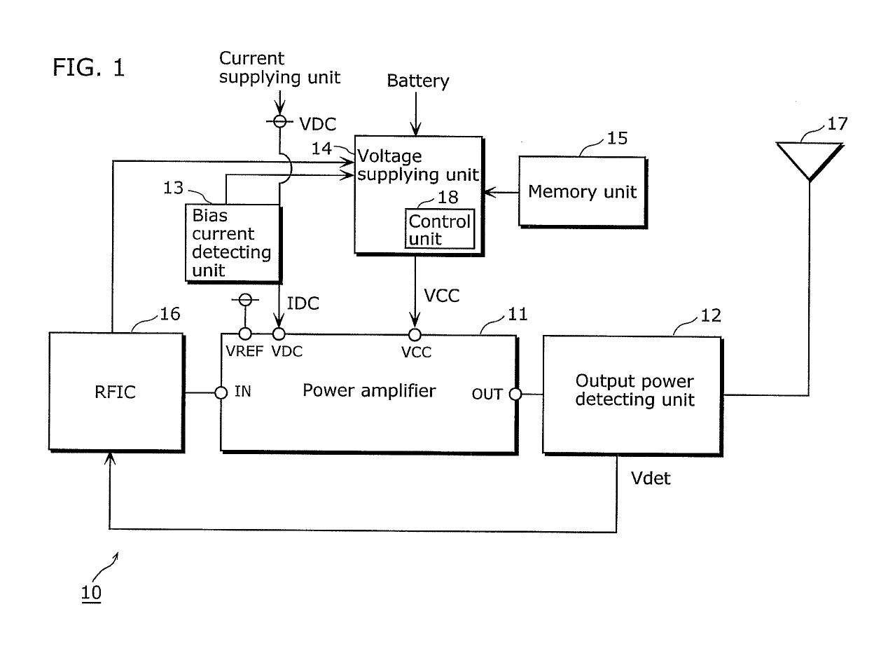

FIG. 1 is a block diagram showing the configuration of the radio frequency power amplifier in the first embodiment according to the present invention.

As shown in FIG. 1, a radio frequency power amplifier 10 in the first embodiment includes an antenna 17, an output power detecting unit 12, a power amplifier 11, an RFIC 16, a bias current detecting unit 13, a voltage supplying unit 14, and a memory unit 15. This radio frequency power amplifier 10 is applied to, for example, a wireless communication device such as a mobile phone terminal. Although not illustrated in this diagram, a typical mobile phone terminal has a duplexer and an antenna switch between the output power detecting unit 12 and the antenna 17 and also has a baseband LSI in an input of the RFIC 16.

Here, an operation performed by the radio frequency power amplifier 10 in the present embodiment is briefly explained.

The antenna 17 shown in FIG. 1 sends a radio frequency signal received from the output power detecting unit 12 and receives a radio frequency signal from a base station. Then, in the radio frequency power amplifier 10, the radio frequency signal received by the antenna 17 is decoded, and the baseband LSI (not shown) performs signal processing on the decoded signal. Following this, the RFIC 16 performs frequency conversion on this processed signal and also performs gain adjustment on a predetermined output. After this, the power amplifier 11 amplifies a transmission signal which is a radio frequency signal provided from the RFIC 16. Hereafter, this transmission signal may be simply referred to as the radio frequency signal. The amplified transmission signal is then radiated via the output power detecting unit 12 and the antenna 17. Here, the output power detecting unit 12 detects output power, which is power of the transmission signal provided from the power amplifier 11, and then performs voltage conversion. The output power detecting unit 12 sends the detected voltage to the RFIC 16. Also, the RFIC 16 sends the information indicating the detected voltage received from the output power detecting unit 12, to the voltage supplying unit 14.

Each component included in the radio frequency power amplifier 10 is explained in detail as follows.

The power amplifier 11, which corresponds to the amplifying unit according to the present invention, amplifies the radio frequency signal received from the RFIC 16. The power amplifier 11 has an input terminal IN, an output terminal OUT, a collector voltage applying terminal VCC, a bias voltage applying terminal VDC, and a reference voltage applying terminal VREF. The radio frequency signal provided from the RFIC 16 is sent to the input terminal IN, where the present radio frequency signal is amplified. After this, the amplified signal is provided from the output terminal OUT. Here, a collector voltage is applied from the voltage supplying unit 14 to the collector voltage applying terminal VCC, and a bias voltage is applied from the bias current detecting unit 13 to the bias voltage applying terminal VDC. Also, a reference voltage is applied to the reference voltage applying terminal VREF, and a bias current IDC is supplied to the bias voltage applying terminal VDC.

Note that the bias voltage VDC and the bias current IDC are supplied from the current supplying unit.

The output power detecting unit 12, which corresponds to the obtaining unit according to the present invention, detects the output power that refers to power of the radio frequency signal provided from the power amplifier 11. Hereafter, the detected output power is referred to as “Vdet”. The output power detecting unit 12 has a directional coupler and a capacitor, for example, and outputs the detected output power Vdet to the RFIC 16. It should be noted that the output power detecting unit 12 may perform voltage conversion on the detected output power Vdet, and may provide a voltage corresponding to the output power Vdet to the RFIC 16. The bias current detecting unit 13, which corresponds to the detecting unit according to the present invention, detects the bias current IDC of the power amplifier 11. The bias current detecting unit 13 has a resistor inserted in a line for detecting the bias current IDC, for example, and then detects the current flowing through the line by measuring a potential difference between the two ends of the present resistor.

The voltage supplying unit 14, which corresponds to the voltage supplying unit according to the present invention, supplies the collector voltage VCC, i.e. the power supply voltage, to the power amplifier 11. To be more specific, the voltage supplying unit 14 compares the detected-voltage information received from the RFIC 16 and the bias current information received from the bias current detecting unit 13 with a reference value stored in association with the output power in the memory unit 15. Then, the voltage supplying unit 14 controls the collector voltage VCC, according to the comparison result.

The voltage supplying unit 14 has a control unit 18. With reference to a bias-current reference value IDCREF as a threshold, the control unit 18 sets the collector voltage at: a first voltage when the bias current IDC detected by the bias current detecting unit 13 is lower than the threshold; a second voltage lower than the first voltage when the bias current IDC detected by the bias current detecting unit 13 is higher than the threshold; and a voltage that is lower than the first voltage and equal to or higher than the second voltage when the bias current IDC detected by the bias current detecting unit 13 is substantially equal to the threshold.

More specifically, when a value representing the bias current IDC detected by the bias current detecting unit 13 is lower than the bias-current reference value IDCREF, the control unit 18 sets the collector voltage at the first voltage. For example, when an output power Pout of the power amplifier 11 is expressed as 22 dBm<Pout≦26 dBm, the collector voltage is set at 4 V, and this voltage is described as “VCC_up” hereafter. When the value representing the bias current IDC detected by the bias current detecting unit 13 is substantially equal to the bias-current reference value IDCREF, the control unit 18 sets the collector voltage at a voltage which is lower than the first voltage and equal to or higher than the second voltage. For example, when the output power Pout of the power amplifier 11 is expressed as 16 dBm<Pout≦22 dBm, the collector voltage is set at 3.5 V, and this voltage is described as “VCC_typ” hereafter. When the value representing the bias current IDC detected by the bias current detecting unit 13 is higher than the bias-current reference value IDCREF, the control unit 18 sets the collector voltage at the second voltage. For example, when the output power Pout of the power amplifier 11 is expressed as 10 dBm<Pout≦16 dBm, the collector voltage is set to 3 V, and this voltage is described as “VCC_down” hereafter.

Here, the bias-current reference value IDCREF indicates a bias current value in association with the output power of the power amplifier 11, the bias current value corresponding to an ideal output load on the radio frequency power amplifier 10. In other words, the bias-current reference value IDCREF indicates the bias current value in association with the output power, corresponding to the case where the output load impedance of the radio frequency power amplifier 10 is 50Ω. To be more specific, the bias-current reference value IDCREF indicates the bias current value in association with the output power, corresponding to the case where an antenna-load voltage standing wave ratio (hereafter, the voltage standing wave ratio is described as the VSWR) is 1:1. That is, the bias current value corresponds to the case where a load impedance seen from the output terminal of the power amplifier 11 to the antenna 17 is ideal (VSWR is 1:1).

The memory unit 15 stores a plurality of bias-current reference values IDCREFs in association with a plurality of values of the output power of the power amplifier 11.

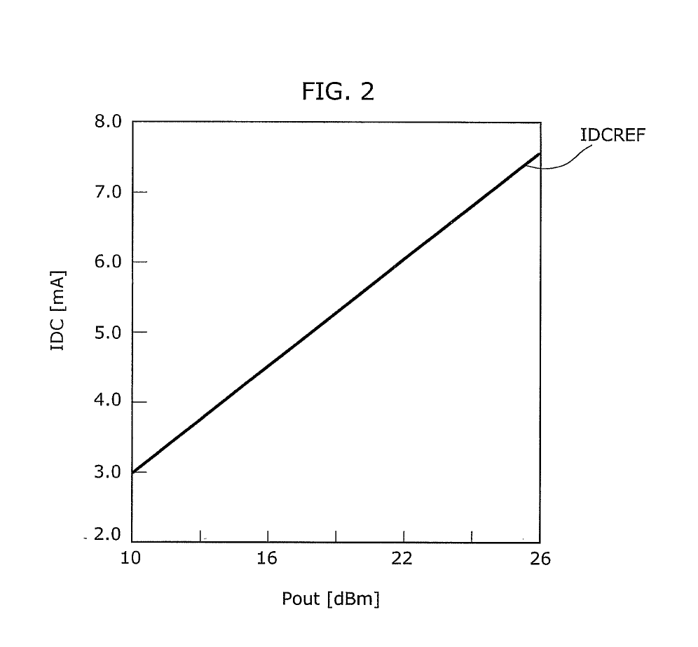

FIG. 2 is a graph showing an example of data held by the memory unit 15.

The graph of FIG. 2 shows the bias-current reference value IDCREF corresponding to the value of the output power, in the case where the load VSWR is 1:1.

As shown in FIG. 2, the reference value IDCREF changes according to the output power of the power amplifier 11. That is, the memory unit 15 stores the plurality of reference values IDCREFs corresponding to the plurality of values of the output power of the power amplifier 11. It should be noted that the memory unit 15 may hold a graph, such as the one shown in FIG. 2, for each of different temperatures of an environment in which the radio frequency power amplifier 10 is implemented.

The control unit 18 uses the bias-current reference value IDCREF shown in FIG. 2 as the threshold. More specifically, the control unit 18 compares the bias-current reference value IDCREF stored in the memory 15 in association with the output power Vdet detected by the output power detecting unit 12 and the value of the bias current IDC detected by the bias current detecting unit 13. On the basis of the comparison result, the control unit 18 sets the collector voltage at: VCC_up when the bias current detected by the bias current detecting unit 13 is lower than the threshold; VCC_typ when the bias current detected by the bias current detecting unit 13 is substantially equal to the threshold; and VCC_down when the bias current detecting by the bias current detecting unit 13 is higher than the threshold.

That is to say, the control unit 18 steps down the collector voltage VCC (i.e., the voltage is set at VCC_down) in a phase where the bias current is higher than the bias-current reference value IDCREF in the case of the VSWR 1:1, steps up the collector voltage VCC (i.e., the voltage is set at VCC_up) in a phase where the bias current is lower than the bias-current reference value IDCREF in the case of the VSWR 1:1, and sets the collector voltage VCC at VCC_typ in a phase where the bias current is substantially equal to the bias-current reference value IDCREF in the case of the VSWR 1:1. Accordingly, a favorable distortion characteristic and a favorable power consumption characteristic can be both achieved.

The RFIC 16 converts a transmission baseband signal provided from the baseband LSI (not shown) into a radio frequency signal, amplifies or attenuates the power of the signal to desired power, and then sends the amplified or attenuated signal to the power amplifier 11. Moreover, the RFIC 16 sends a signal indicating the output power Vdet detected by the output power detecting unit 12, to the voltage supplying unit 14. Here, the power of the radio frequency signal provided from the RFIC 16 is determined from: the output power of the antenna 17 that is required of the radio frequency power amplifier 10; and the attenuation amount or the amplification gain of the power amplifier 11, the output power detecting unit 12, and the antenna 17.

As described, the radio frequency power amplifier 10 in the present embodiment includes: the power amplifier 11 which amplifies a radio frequency signal; the voltage supplying unit 14 which supplies the collector voltage VCC to the power amplifier 11; the current supplying unit which supplies the bias current IDC to the power amplifier 11; and the bias current detecting unit 13 which detects the bias current IDC. Here, the voltage supplying unit 14 sets the collector voltage at: VCC_up when the detected bias current IDC is lower than the bias-current reference value IDCREF; VCC_typ when the detected bias current IDC is substantially equal to the reference value IDCREF; and VCC_down lower than VCC_up when the detected bias current IDC is higher than the reference value IDCREF.

With this configuration, the radio frequency power amplifier 10 in the present embodiment can achieve a favorable high frequency characteristic without using an isolator and can reduce power consumption at the same time.

Next, a specific configuration of this radio frequency power amplifier 10 is explained.

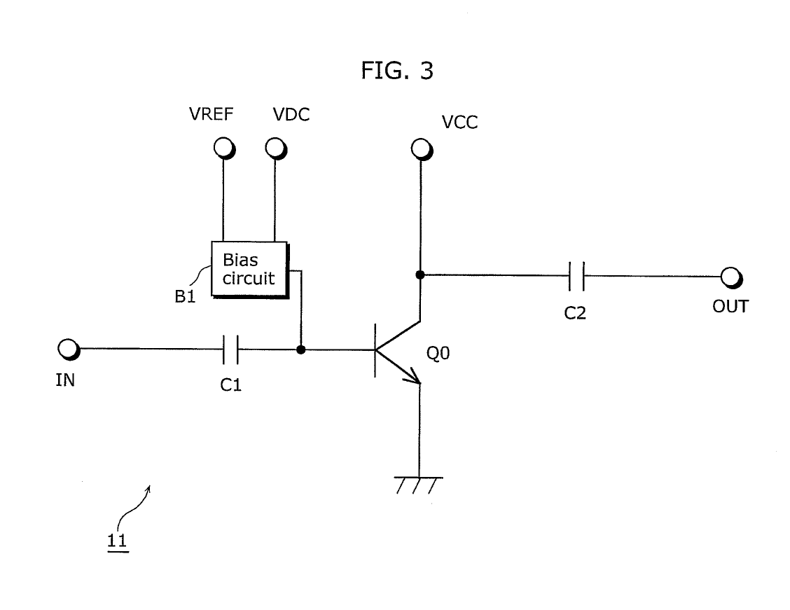

FIG. 3 is a schematic circuit diagram showing a specific configuration of the power amplifier 11 in the first embodiment according to the present invention.

As shown in FIG. 3, the power amplifier 11 has a power amplifying transistor Q0, the input terminal IN, the output terminal OUT, a bias circuit B1, capacities C1 and C2, the collector voltage applying terminal VCC, the bias voltage applying terminal VDC, and the reference voltage applying terminal VREF.

The radio frequency signal provided from the RFIC 16 to the power amplifier 11 is sent to the input terminal IN. The radio frequency signal received by the input terminal IN is amplified by the power amplifying transistor Q0, and then provided to the output terminal OUT. Here, the output power range of the power amplifier 11 is about from −50 dBm to +26 dBm in the case of a UMTS system.

The power amplifying transistor Q0 is, for example, a bipolar transistor having: a base which is connected to the input terminal IN via the capacity C1; a collector which is connected to the collector voltage applying terminal VCC; and an emitter which is grounded. The base of the power amplifying transistor Q0 is further connected to the bias circuit B1 and is supplied with the bias current IDC. The collector of the power amplifying transistor Q0 is further connected to the output terminal OUT via the capacity C2, and provides the radio frequency signal amplified by the power amplifying transistor Q0 from the output terminal OUT to the output power detecting unit 12.

The bias circuit B1 is connected to the reference voltage applying terminal VREF, the bias voltage applying terminal VDC, and the power amplifying transistor Q0. The bias circuit B1 supplies the bias current IDC from the bias current applying terminal VDC to the power amplifying transistor Q0. The detailed configuration of the bias circuit B1 is described later.

The capacity C1 is employed to provide matching for the input side of the power amplifying transistor Q0. The capacity C2 is employed to provide matching for the output side of the power amplifying transistor Q0, and to reject a DC component.

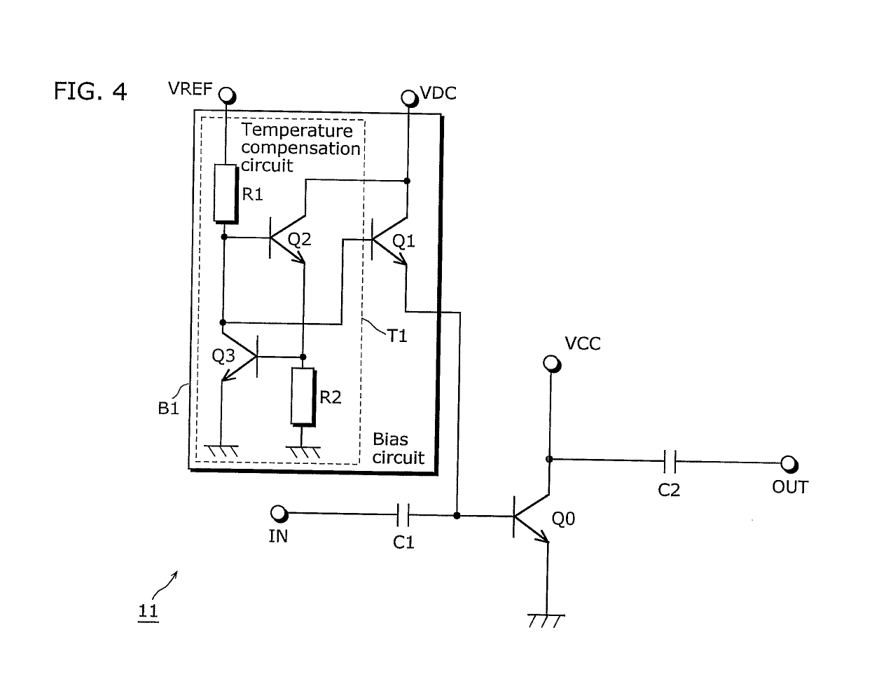

FIG. 4 is a schematic circuit diagram showing a specific configuration of the bias circuit B1 of the power amplifier 11.

The bias circuit B1 has a bias current supplying transistor Q1 and a temperature compensation circuit T1. The temperature compensation circuit T1 has resistors R1 and R2 and transistors Q2 and Q3.

The bias current supplying transistor Q1 corresponds to the current control transistor according to the present invention. The bias current supplying transistor Q1 is, for example, a bipolar transistor which forms an emitter-follower circuit for supplying a base current of the power amplifying transistor Q0. This bias current supplying transistor Q1 has: an emitter which is connected to the base of the power amplifying transistor Q0; a collector which is connected to the bias voltage applying terminal VDC; and a base which is connected to the temperature compensation circuit T1. With this configuration, the bias current supplying transistor Q1 is temperature compensated by the temperature compensation circuit T1, and thus the bias current IDC is also temperature compensated. This means that the power amplifying transistor Q0 is temperature compensated as well.

The temperature compensation circuit T1 switches between Active and Inactive of the power amplifier 11, using the voltage applied by the reference voltage applying terminal VREF. Also, the temperature compensation circuit T1 performs temperature compensation on the bias current supplying transistor Q1 and the power amplifying transistor Q0. It should be noted that the configuration of the temperature compensation circuit T1 is not limited to the one shown in FIG. 4. For example, a diode may be employed in the configuration.

As described, the power amplifier 11 amplifies the radio frequency signal received from the RFIC 16, and provides the amplified signal to the antenna 17 via the output power detecting unit 12.

Next, the high frequency characteristic and power consumption of the radio frequency power amplifier 10 configured as described so far are explained. The explanation is given based on: (i) the case where the collector voltage VCC of the power amplifier 11 is 4 V; and (ii) the case where the collector voltage VCC of the power amplifier 11 is 3 V. In these two cases, the load impedance condition is changed.

(i) Case where the collector voltage VCC of the power amplifier 11 is 4 V

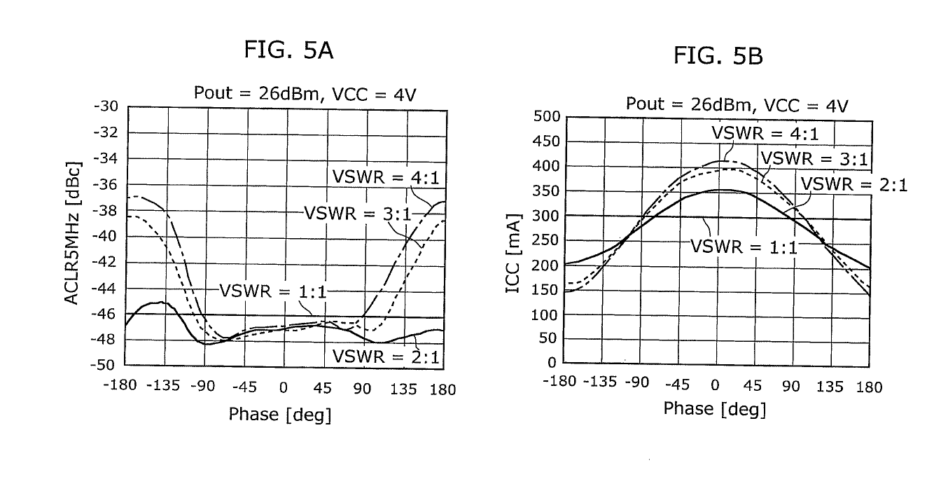

FIG. 5A is a graph showing a characteristic of the adjacent channel leakage ratio (ACLR) at 5-MHz offset when the collector voltage is 4 V. Hereafter, this characteristic is referred to as the “ACLR5 MHz characteristic”. FIG. 5B is a graph showing a collector current (ICC) characteristic when the collector voltage is 4 V.

In this case, the conditions are that: the frequency is 824 MHz; the signal is a UMTS (based on High Speed Downlink Packet Access (HSDPA)) modulated signal; the reference voltage VREF of 2.9 V is applied; the bias voltage VDC of 2.9 V is applied; and the input power of the power amplifier 11 is adjusted so as to be 26 dBm when detected by the output power detecting unit 12. More specifically, the gain of the RFIC 16 is adjusted here. The ACLR characteristic is an indicator representing the distortion characteristic of the power amplifier 11.

Moreover, as the condition of changes in the load impedances of the output power detecting unit 12 and the power amplifier 11, the VSWR range is from 1:1 to 4:1. That is, the load VSWR range of the output power detecting unit 12 is from 1:1 to 4:1. Hereafter, the load VSWR of the power amplifier 11 refers to the load VSWRs of the output power detecting unit 12 and the power amplifier 11. The reason why the load VSWR range is from 1:1 to 4:1 is given as follows. Even when the impedance of the antenna 17 changes so significantly that the antenna load condition disables communication (such as when the antenna load VSWR is 20:1), the load VSWR of the power amplifier 11 does not exceed 4:1 because of the insertion loss of at least about 2 dB caused by the typical duplexer and antenna switch located between the output power detecting unit 12 and the antenna 17. In other words, this load VSWR of the power amplifier 11 from 1:1 to 4:1 practically accommodates almost all the load states.

Here, the value representing the ACLR5 MHz characteristic shown in FIG. 5A needs to be equal to or lower than −35 dBc to satisfy the specifications defined by the standards such as the Ratio Act. To be more specific, it is specified in the Third Generation Partnership Project (3GPP) that the value of the ACLR5 MHz characteristic of a mobile phone terminal is equal to or lower than −33 dBc. In consideration of the characteristic degradation distributed among the other units (such as the antenna 17, the duplexer, and the antenna switch), the value representing the ACLR5 MHz characteristic of the power amplifier 11 and the output power detecting unit 12 needs to be equal to or lower than −35 dBc.

As can be seen from FIG. 5A, when the collector voltage VCC of the power amplifier 11 is 4 V, the ACLR5 MHz characteristic stays below −35 dBc to satisfy the specifications in all the phases of the load VSWRs from 1:1 to 4:1.

In FIG. 5B, on the other hand, the higher the load VSWR is, the larger the changes in the collector current (ICC) characteristic of the power amplifier 11 with respect to the phases.

From a comparison between FIGS. 5A and 5B, it can be understood that, in the phases where each of the values representing the collector current characteristics in the cases of the load VSWRs 2:1, 3:1, and 4:1 is higher than the value representing the collector current characteristic in the case of the load VSWR 1:1 (namely, the phases from −90 deg to +110 deg), each ACLR5 MHz characteristic of the load VSWRs has a margin of at least 8 dB at worst with respect to the specifications. That is to say, in the phase where the value representing the collector current characteristic is higher than that in the case of the load VSWR 1:1, the ACLR5 MHz characteristic is extremely favorable. However, this means that an excessive amount of power is consumed here.

In the phases where each of the values representing the collector current characteristics in the cases of the load VSWRs 2:1, 3:1, and 4:1 is lower than the value representing the collector current characteristic in the case of the load VSWR 1:1 (namely, the phases from +110 deg to +180 deg and from −180 deg to −90 deg), each ACLR5 MHz characteristic of the load VSWRs has only a small margin with respect to the specifications. Here, this means that the power consumption is relatively low.

(ii) Case where the collector voltage VCC of the power amplifier 11 is 3 V

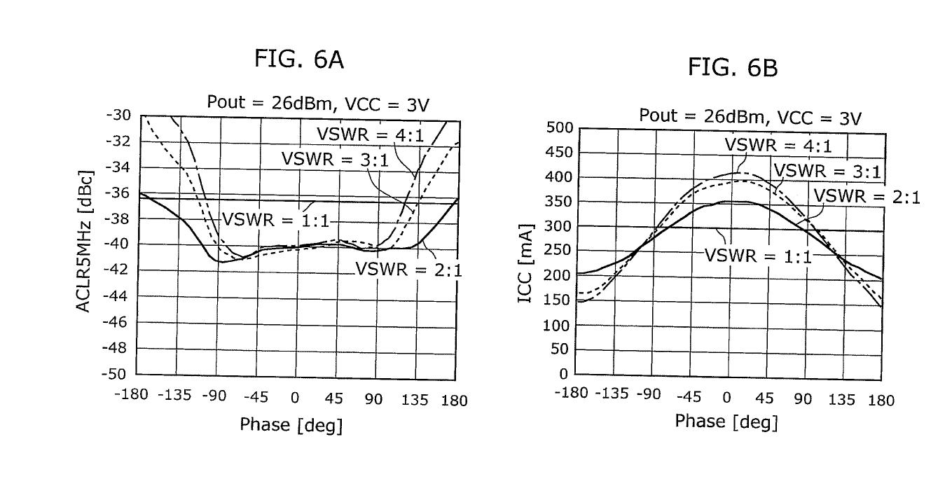

FIG. 6A is a graph showing the ACLR5 MHz characteristic when the collector voltage is 3 V. FIG. 6B is a graph showing the collector current (ICC) characteristic when the collector voltage is 3 V.

The conditions in the present case are the same as those in the case (i) where the collector voltage VCC is 4 V. To be more specific, the conditions are that: the frequency is 824 MHz; the signal is a UMTS (based on HSDPA) modulated signal; the reference voltage VREF of 2.9 V is applied; the bias voltage VDC of 2.9 V is applied; and the input power of the power amplifier 11 is adjusted so as to be 26 dBm when detected by the output power detecting unit 12. More specifically, the gain of the RFIC 16 is adjusted here.

As can be seen from FIG. 6A, when the collector voltage VCC of the power amplifier 11 is 3 V, the ACLR5 MHz characteristic stays below −35 dBc to satisfy the specifications in all the phases of the load VSWRs 1:1 and 2:1. However, as to the cases of the load VSWRs 3:1 and 4:1, there are phases in which the ACLR5 MHz characteristic does not satisfy the specifications. More specifically, after the load VSWR exceeds 2:1, there are phases in which the the ACLR5 MHz characteristic does not satisfy the specifications.

In this way, as compared to the ACLR5 MHz characteristic in the case of the collector voltage of 4 V as shown in FIG. 5A, the ACLR5 MHz characteristic in the case of the collector voltage of 3 V as shown in FIG. 6A is degraded in all the phases.

On the other hand, the collector current (ICC) characteristic of the power amplifier 11 in the case where the collector voltage VCC is 3 V as shown in FIG. 6B is almost identical to the collector current (ICC) characteristic of the power amplifier 11 in the case where the collector voltage VCC is 4 V as shown in FIG. 5B. That is to say, the collector current (ICC) characteristic of the power amplifier 11 does not depend on the collector voltage VCC.

From a comparison between FIGS. 6A and 6B, it can be understood that, in the phases where each of the values representing the collector current characteristics in the cases of the load VSWRs 2:1, 3:1, and 4:1 is higher than the value representing the collector current characteristic in the case of the load VSWR 1:1 (namely, the phases from −90 deg to +110 deg), each ACLR5 MHz characteristic of the load VSWRs has a margin of at least about 2 dB at worst with respect to the specifications. In this case here, the power consumption by the radio frequency power amplifier 10 can be reduced by 25% as compared to the case where the collector voltage VCC is 4 V.

In the phases where each of the values representing the collector current characteristics in the cases of the load VSWRs 2:1, 3:1, and 4:1 is lower than the value representing the collector current characteristic in the case of the load VSWR 1:1 (namely, the phases from +110 deg to +180 deg and from −180 deg to −90 deg), the ACLR5 MHz characteristics of the load VSWRs do not always satisfy the specifications.

From the results obtained in the cases (i) and (ii) explained with reference to FIGS. 5A, 5B, 6A, and 6B, the following can be understood. Suppose that the load impedance changes in the state where the output power of the power amplifier 11 is 26 dBm, as described above. In this state, applying the collector voltage of 3 V in the phases where the collector current ICC is higher than that in the case of the load VSWR 1:1 (namely, the phases from −90 deg to +110 deg) and applying the collector voltage of 4 V in the phases where the collector current ICC is lower than that in the case of the load VSWR 1:1 (namely, the phases from +110 deg to +180 deg and from −180 deg to −90 deg) is the most effective way to satisfy the specifications of the ACLR5 MHz characteristic and reduce power consumption as much as possible at the same time.

Thus, by controlling the collector voltage VCC, the distortion characteristic can be prevented from degrading and, at the same time, the power consumption can be reduced. However, as mentioned in “Summary of the Invention” above, when the high current that flows in the case of high output power is detected, a large amount of power is consumed. On this account, it is difficult to achieve the favorable distortion characteristic and the low power consumption at the same time.

The base current of the power amplifying transistor Q0 shown in FIGS. 3 and 4 is equivalent to a value obtained by dividing the collector current ICC by a current amplification gain, and thus can be detected using a relatively small amount of power. In the present embodiment, instead of measuring the collector current ICC, the bias current detecting unit 13 detects the bias current IDC passing through the bias voltage applying terminal VDC, which corresponds to the base current of the power amplifying transistor Q0. As a result, the power consumption can be reduced.

To be more specific, the bias current and the collector current can be expressed by the following expression, where the bias current is Ib, the collector current is Ic, and the current amplification gain is h_{FE}.

Ib×h_{FE}=Ic Expression 1

The value representing the bias current IDC passing through the bias voltage applying terminal VDC is slightly different from the value representing the base current of the power amplifying transistor Q0. However, note that the bias current IDC passing through the bias voltage applying terminal VDC shows the same behavior as the base current of the power amplifying transistor Q0. To be more specific, the bias current IDC is slightly different from the base current of the power amplifying transistor Q0 because the bias current IDC flows through the transistor Q1 of the temperature compensation circuit T1 as well. However, the bias current IDC shows the same characteristics as the base current, except for the amount of current. On account of this, there is no problem in measuring (or, detecting) the bias current IDC instead of directly measuring the base current. Since the magnitude relation in the bias current characteristic between the load VSWR 1:1 and the other load VSWR5 (namely, 2:1, 3:1, and 4:1) does not change, the collector voltage may be set according to the bias current characteristic.

Next, the explanations are given about the effect of reducing the power consumption through the bias current detection and about the relation between the bias current characteristic and the collector current characteristic, on the basis of the bias current characteristic of the power amplifier 11.

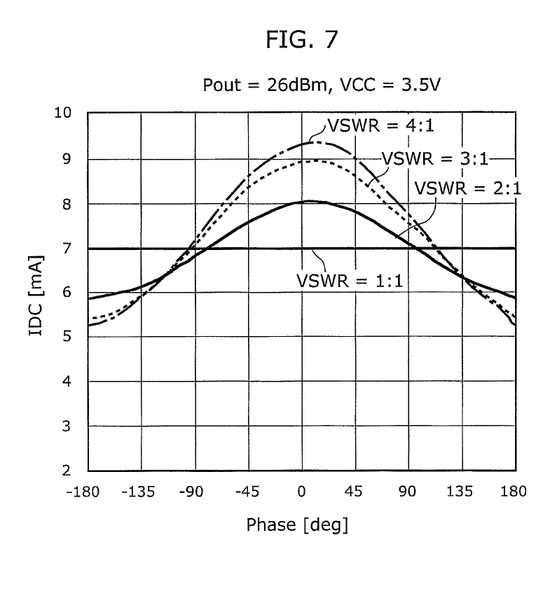

FIG. 7 is a graph showing the bias current (IDC) characteristic when the collector voltage is 3.5 V.

The conditions in the present case are the same as those in the cases (i) and (ii). To be more specific, the conditions are that: the frequency is 824 MHz; the signal is a UMTS (based on HSDPA) modulated signal; the reference voltage VREF of 2.9 V is applied; the bias voltage VDC of 2.9 V is applied; and the input power of the power amplifier 11 is adjusted so as to be 26 dBm when detected by the output power detecting unit 12. More specifically, the gain of the RFIC 16 is adjusted here. As is the case with the collector current (ICC) characteristic, the bias current (IDC) shows almost the same characteristic when the range of the collector voltage VCC is from 3 V to 4 V. For this reason, the case where the collector voltage VCC is 3.5 V is shown here.

As shown in FIG. 7, even with the changes in the load impedance, the bias current IDC at the maximum does not exceed 10 mA. From this, it can be understood that the bias current IDC is 1/40 of 420 mA which is the maximum value representing the collector current ICC. With this being the state, when the bias current detecting unit 13 detects the bias current IDC using a monitor resistance of 2.5Ω, the power consumption by the bias current detecting unit 13 is expressed by the following expression.

Power consumption by the bias current detecting unit 13=(10 mA)̂2*2.5Ω=0.25 mW Expression 2

Suppose, for example, that a detecting unit which detects the collector current ICC is provided in place of the bias current detecting unit 13 which detects the bias current IDC. In such a case, the power consumption by this detecting unit is expressed by the following expression.

(420 mA)̂2*2.5Ω=441 mW Expression 3

As apparent from Expressions 2 and 3, the power consumption can be reduced to about 1/1700 by detecting the bias current IDC instead of detecting the collector current ICC.

When the load VSWR of the power amplifier 11 is 1:1, the collector voltage VCC of 3.5 V is required, considering that a margin of at least 2 dB needs to be ensured to satisfy the specifications of the ACLR5 MHz characteristic. Therefore, the power consumption by the power amplifier 11 is expressed by the following expression.

Power consumption by the power amplifier 11 (VSWR=1:1)=3.5 V*300 mA=1050 mW Expression 4

As described, the power consumption by the bias current detecting unit 13 is extremely small as compared to the power consumption by the power amplifier 11. On this account, it is obvious that an increase in power consumption can be prevented by detecting the bias current IDC.

Also, as can be seen from FIG. 7, the phases where the bias current IDC is higher than that in the case where VSWR=1:1 are from −90 deg to +110 deg, and the phases where the bias current IDC is lower than that in the case where VSWR=1:1 are from +110 deg to +180 deg and from −180 deg to −90 deg.

This agrees with the result regarding the collector current (ICC) characteristic shown in FIGS. 5B and 6B.

To be more specific, suppose that the load impedance changes in the state where the output power of the power amplifier 11 is 26 dBm, as described above. In this state, applying the collector voltage of 3 V in the phases where the bias current IDC is higher than that in the case where VSWR=1:1 (namely, the phases from −90 deg to +110 deg) and applying the collector voltage of 4 V in the phases where the bias current IDC is lower than that in the case where VSWR=1:1 (namely, the phases from +110 deg to +180 deg and from −180 deg to −90 deg) is the effective way to satisfy the specifications of the ACLR5 MHz characteristic and reduce power consumption as much as possible at the same time.

The explanation has been given about the case where the output power is 26 dBm. Even when the output power of the power amplifier 11 is other than 26 dBm, the same control as described may be performed according to the corresponding output power. To be more specific, the control unit 18 may control the collector voltage VCC according to the output power of the power amplifier 11.

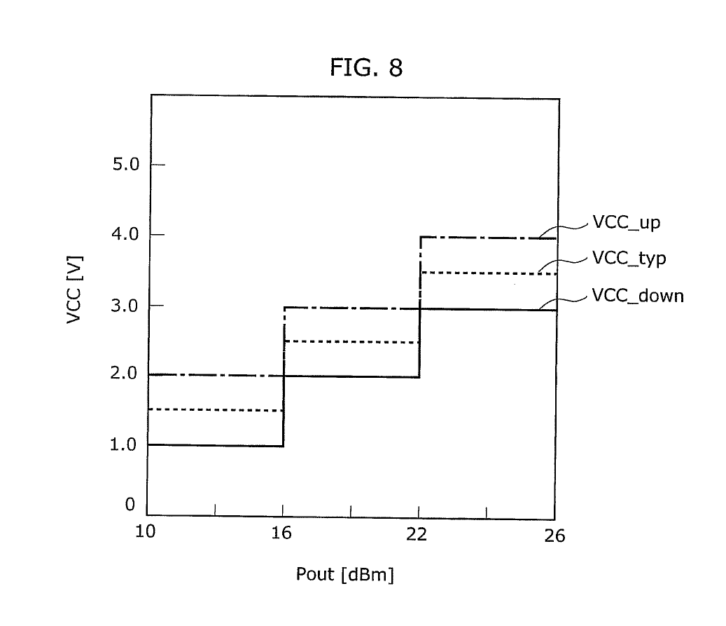

FIG. 8 is a graph showing set values of the collector voltage (VCC), in association with the output power of the power amplifier 11 included in the radio frequency power amplifier 10 in the first embodiment according to the present invention. This graph may be stored in the memory unit 15 or in the control unit 18.

As shown in FIG. 8, the control unit 18 sets a first upper-limit voltage (4 V, for example) as VCC_up when the output power of the power amplifier 11 is higher than a first power (22 dBm, for example), and sets a second upper-limit voltage (3 V, for example) which is lower than the first upper-limit voltage as VCC_down when the output power of the power amplifier 11 is equal to or lower than the first power. Moreover, the control unit 18 sets a voltage higher than the second upper-limit voltage (higher than 3 V, for example) as VCC_down when the output power of the power amplifier 11 is higher than the first power.

Here, the set values of the collector voltage shown in FIG. 8 are determined, considering that a margin of at least 2 dB needs to be ensured to satisfy the specifications of the ACLR5 MHz characteristic. To be more specific, VCC_down indicates a voltage for causing the ACLR5 MHz characteristic of the radio frequency power amplifier 10 to be lower than a predetermined value when the detected bias current IDC is higher than the reference value IDCREF. Accordingly, the specifications based on the laws and regulations, such as the Radio Act, can be satisfied and the power consumption can be reduced at the same time. In other words, unnecessary radiation can be prevented and the power consumption can thus be reduced. Also, VCC_up indicates a voltage for causing the ACLR5 MHz characteristic of the radio frequency power amplifier 10 to be lower than the predetermined value regardless of the value of the bias current IDC. With this, the specifications based on the laws and regulations, such as the Radio Act, can always be satisfied. This is to say, unnecessary radiation can be reliably prevented in any load condition. Moreover, VCC_typ indicates a voltage for causing the ACLR5 MHz characteristic of the radio frequency power amplifier 10 to be lower than the predetermined value when the detected bias current IDC is substantially equal to the reference value IDCREF.

Here, the predetermined value is calculated based on the specifications of the ACLR5 MHz characteristic required of the radio frequency power amplifier 10. For example, the predetermined value is −35 dBc, which allows for a margin of 2 dB in −33 dBc specified in 3GPP.

Thus, as shown in FIG. 8, when the output power range is from 22 dBm to 26 dBm (i.e., 26 dBm≧Output power Pout>22 dBm), the collector voltage is set as: VCC_up=4 V; VCC_down=3 V; or VCC_typ=3.5 V. When the output power range is from 16 dBm to 22 dBm (i.e., 22 dBm≧Output power Pout>16 dBm), the collector voltage is set as: VCC_up=3 V; VCC_down=2 V; or VCC_typ=2.5 V. When the output power range is from 10 dBm to 16 dBm (i.e., 16 dBm≧Output power Pout>10 dBm), the collector voltage is set as: VCC_up=2 V; VCC_down=1 V; or VCC_typ=1.5 V.

When the output power falls below 10 dBm, the bias current is identical to an idling current and, therefore, the current detection becomes difficult. However, in the case of the low output of 10 dBm or lower, it is hard to recognize the influence of changes in the load impedance. Thus, it is only necessary to set the collector voltage VCC so that a margin of at least 2 dB is ensured to satisfy the specifications of the ACLR5 MHz characteristic when VSWR=1:1. With this, the specifications of the ACLR5 MHz characteristic can be easily satisfied.

As described thus far, the radio frequency power amplifier 10 in the present embodiment includes: the power amplifier 11 which amplifies a radio frequency signal; the voltage supplying unit 14 which supplies the collector voltage VCC to the power amplifier 11; the current supplying unit which supplies the bias current IDC to the power amplifier 11; and the bias current detecting unit 13 which detects the bias current IDC. Here, the voltage supplying unit 14 sets the collector voltage at: VCC_up when the detected bias current IDC is lower than the bias-current reference value IDCREF; VCC_typ when the detected bias current IDC is substantially equal to the reference value IDCREF; and VCC_down lower than VCC_up when the detected bias current IDC is higher than the reference value IDCREF.

With this configuration, the radio frequency power amplifier 10 in the present embodiment can achieve a favorable high frequency characteristic without using an isolator and can reduce power consumption at the same time.

Next, an operation performed by the radio frequency power amplifier 10 configured as described above in the first embodiment according to the present invention is explained.

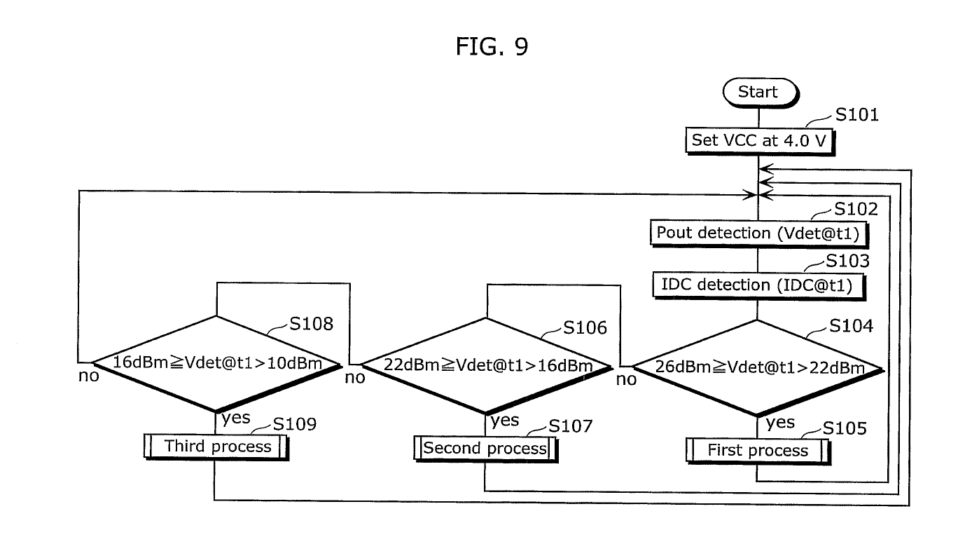

FIG. 9 is a flowchart showing the operation performed by the radio frequency power amplifier 10 in the first embodiment according to the present invention.

First, the control unit 18 sets the collector voltage VCC at 4 V (step S101). By setting the collector voltage VCC at 4 V, the ACLR5 MHz characteristic can be ensured at any conceivable load impedance. The impedance level is unknown in the initial state and, for this reason, the voltage that reliably satisfies the specifications is first set. In other words, unnecessary radiation can be reliably prevented.

Next, the output power detecting unit 12 detects the output power Pout of the power amplifier 11 (step S102). Then, information indicating the detected output power Pout is provided to the control unit 18 via the RFIC 16. Hereafter, this output power Pout detected by the output power detecting unit 12 is referred to as “Vdet@t1”.

In this state, the bias current detecting unit 13 detects the bias current IDC (step S103). To be more specific, the bias current detecting unit 13 detects the bias current IDC in the state where there is no change in the output power detected in the process (step S102) of detecting the output power Pout. Hereafter, this bias current IDC detected by the bias current detecting unit 13 is referred to as “IDC@t1”.

Next, the control unit 18 determines whether or not the output power detected by the output power detecting unit 12 exceeds 22 dBm and equal to or lower than 26 dBm (step S104). More specifically, the control unit 18 determines whether or not Vdet@t1 is higher than 22 dBm and equal to or lower than 26 dBm. When Vdet@t1 is higher than 22 dBm and equal to or lower than 26 dBm (yes in step S104), the control unit 18 proceeds to a first process (step S105).

When a different value is detected as the output power, the control unit 18 proceeds to a process provided for the case of a different output power.

More specifically, when Vdet@t1 is not higher than 22 dBm and is not equal to nor lower than 26 dBm (no in step S104), the control unit 18 determines whether Vdet@t1 is higher than 16 dBm and equal to or lower than 22 dBm (step S106). When Vdet@t1 is higher than 16 dBm and equal to or lower than 22 dBm (yes in step S106), the control unit 18 proceeds to a second process (step S107).

When Vdet@t1 is not higher than 16 dBm and is not equal to nor lower than 22 dBm (no in step S106), the control unit 18 determines whether Vdet@t1 is higher than 10 dBm and equal to or lower than 16 dBm (step S108). When Vdet@t1 is higher than 10 dBm and equal to or lower than 16 dBm (yes in step S108), the control unit proceeds to a third process (step S109).

When Vdet@t1 is not higher than 10 dBm and is not equal to nor lower than 16 dBm (no in step S108), the control unit 18 returns to the process where the output power Pout of the power amplifier 11 is detected (step S102) and thus repeats the aforementioned series of processes periodically.

As described, the control unit 18 proceeds to: the first process (step S105) when 26 dBm≧Vdet@t1>22 dBm; the second process (step S107) when 22 dBm≧Vdet@t1>16 dBm; or the third process (step S109) when 16 dBm≧Vdet@t1>10 dBm. Otherwise, the control unit 18 repeats the aforementioned series of processes.

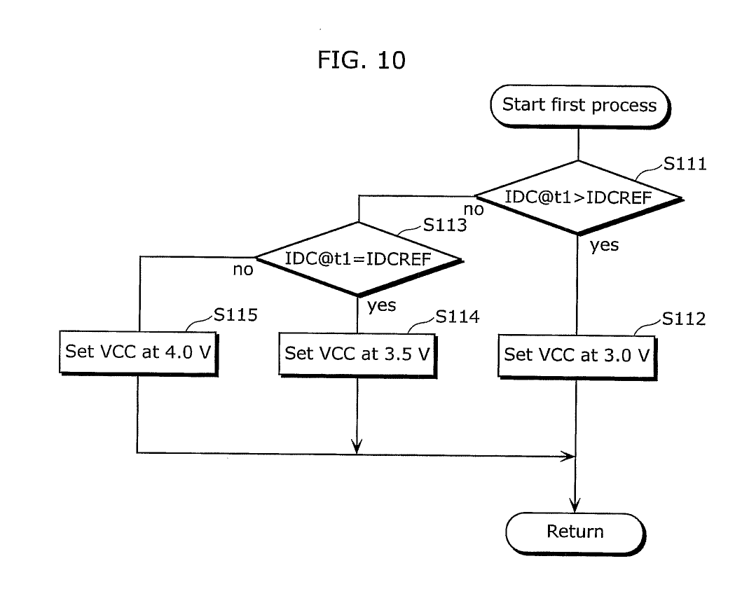

FIG. 10 is a flowchart showing a specific process performed in the first process (step S105) shown in FIG. 9. To be more specific, FIG. 10 shows how the control unit 18 sets the collector voltage as: VCC_up=4 V; VCC_down=3 V; or VCC_typ=3.5 V, corresponding to changes in the load impedance of the case where the output power range is from 22 dBm to 26 dBm, namely, 26 dBm≧Vdet@t1>22 dBm.

First, the control unit 18 compares the bias current IDC@t1 and the bias-current reference value IDCREF which is used as a standard of reference corresponding to the present output power Vdet@t1. More specifically, the control unit 18 obtains, from the graph shown in FIG. 2, the bias-current reference value IDCREF corresponding to the output power Vdet@t1, and compares the bias current IDC@t1 and the obtained reference value IDCREF. Then, the control unit 18 determines whether or not the bias current IDC@t1 detected by the bias current detecting unit 13 is higher than the reference value IDCREF (step S111).

When the bias current IDC@t1 is higher than the reference value IDCREF (yes in step S111), the control unit 18 sets the collector voltage VCC at 3.0 V (step S112). Thus, the voltage supplying unit 14 supplies the collector voltage VCC of 3.0 V to the power amplifier 11.

When the bias current IDC@t1 is not higher than the reference value IDCREF (no in step S111), the control unit 18 proceeds to a different process. To be more specific, the control unit 18 determines whether or not the bias current IDC@t1 is equal to the reference value IDCREF (step S113). When the bias current IDC@t1 is equal to the reference value IDCREF (yes in step S113), the control unit 18 sets the collector voltage VCC at 3.5 V (step S114). Thus, the voltage supplying unit 14 supplies the collector voltage VCC of 3.5 V to the power amplifier 11.

When the bias current IDC@t1 is not equal to the reference value IDCREF (no in step S113), the control unit 18 sets the collector voltage VCC at 4.0 V (step S115). Thus, the voltage supplying unit 14 supplies the collector voltage VCC of 4.0 V to the power amplifier 11. It should be noted that when the bias current IDC@t1 is determined to be equal to the reference value IDCREF, this does not mean that IDC@t1 is precisely equal to IDCREF. That is, the case where IDC@t1 is substantially equal to IDCREF is included as well. For example, when the value representing the bias current IDC@t1 is within plus or minus 10 percent of the reference value IDCREF, IDC@t1 is determined to be equal to IDCREF.

In this way, the control unit 18 compares the bias-current reference value IDCREF corresponding to the output power Vdet@t1 detected by the output power detecting unit 12 and the bias current IDC@t1 detected by the bias current detecting unit 13. Then, the control unit 18 controls the collector voltage VCC according to the result of the comparison.

After the process (one of steps S112, S114, and S115) of setting the collector voltage VCC, the control unit 18 terminates the first process (step S105).

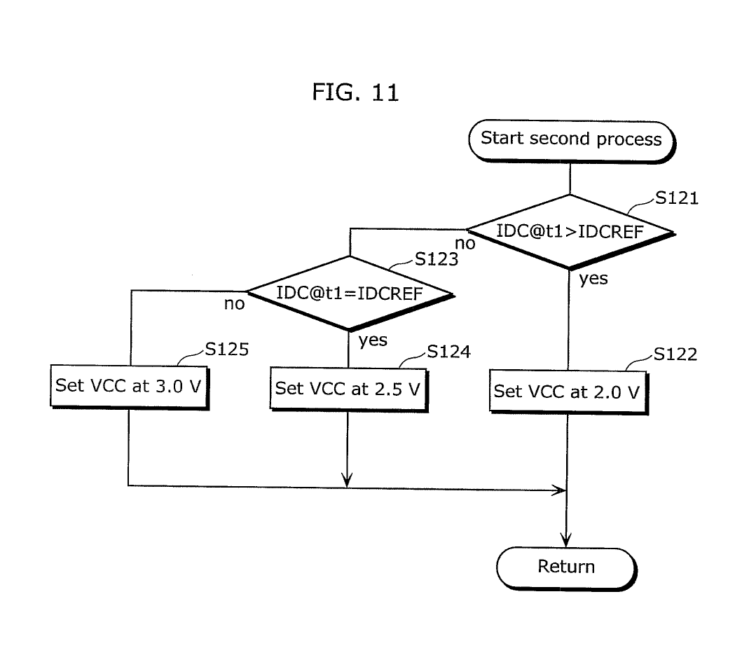

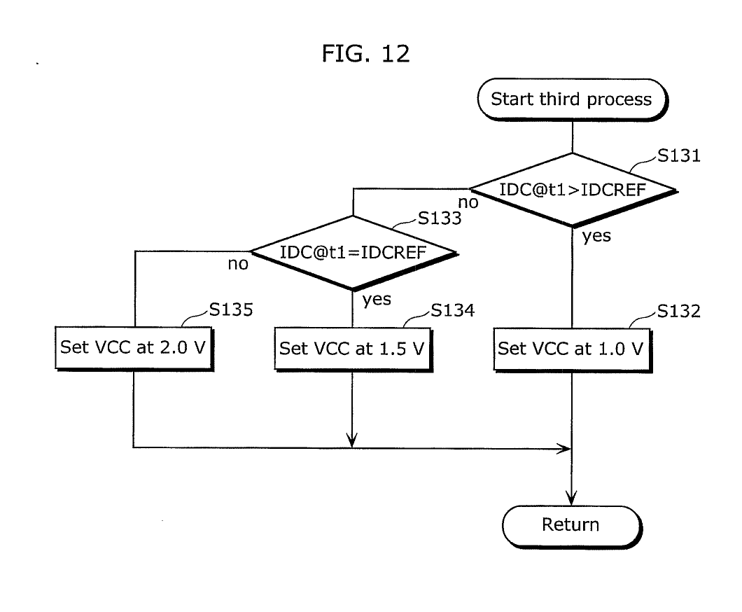

FIG. 11 is a flowchart showing a specific process performed in the second process (step S107) shown in FIG. 9. FIG. 12 is a flowchart showing a specific process performed in the third process (step S109) shown in FIG. 9.

The flowcharts of the second process (step S107) shown in FIG. 11 and the third process (step S109) shown in FIG. 12 are almost the same as the flowchart of the first process (step S105) shown in FIG. 10. However, the second process (step S107) and the third process (step S109) are different from the first process (step S105) in the output power Vdet@t1 detected by the output power detecting unit 12. As apparent from the graph shown in FIG. 2, the bias-current standard value IDCREF, which is used as a standard of reference, is different in each of steps S121, S123, S131, and S133. Moreover, as apparent from the graph shown in FIG. 8, the collector voltage to be set is different in each of steps S122, S124, S125, S132, S134, and S135.

Thus, in the case where 22 dBm Output power Vdet@t1>16 dBm and the case where 16 dBm Output power Vdet@t1>10 dBm, the control unit 18 uses, for a comparison operation, the bias-current reference value IDCREF that is shown in FIG. 2 and is previously stored in association with the output power in the memory unit 15, as in the case where 26 dBm≧Output power Vdet@t1>22 dBm. On the basis of the comparison result, the collector voltage VCC is set as shown in FIG. 8. More specifically, on the basis of the result of the comparison between the bias current IDC@t1 and the bias-current reference value IDCREF: 2.0 V, 2.5 V, or 3.0 V is set as the collector voltage in the second process; and 1.0 V, 1.5 V, or 2.0 V is set as the collector voltage in the third process.

Then, after completing the first process (step S105), the second process (step S107), or the third process (step S109), the control unit 18 returns to the process of detecting the output power Pout of the power amplifier 11 (step S102) and repeats the aforementioned series of processes periodically.

As described, the control unit 18 periodically compares the bias current IDC@t1 and the bias-current reference value IDCREF, and controls the collector voltage according to the comparison result. For example, when the collector voltage is currently set at VCC_up and the bias current IDC@t1 becomes higher than the bias-current reference value IDCREF, the control unit 18 changes the collector voltage VCC from VCC_up to VCC_down. With this, even when the load impedance changes during communication, the radio frequency power amplifier 10 can reduce power consumption. Moreover, when the collector voltage is currently set at VCC_down and the bias current IDC@t1 becomes lower than the bias-current reference value IDCREF, the control unit 18 changes the collector voltage VCC from VCC_down to VCC_up. With this, even when the load impedance changes during communication, the radio frequency power amplifier 10 can achieve a favorable distortion characteristic.

According to the operation described thus far, the radio frequency power amplifier 10 in the present embodiment can satisfy the specifications of the ACLR5 MHz characteristic and reduce power consumption at the same time even when the antenna impedance of the output power changes.

Here, power consumptions are compared between a radio frequency power amplifier using an isolator and the power amplifier 10 in the present embodiment.

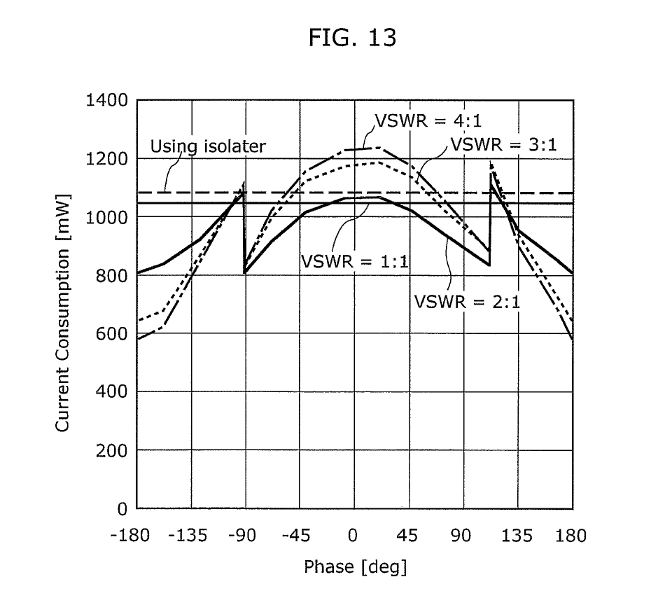

FIG. 13 is a graph showing a characteristic of power consumption with respect to changes in the load impedance of the radio frequency power amplifier 10 in the first embodiment according to the present invention.

Power consumption shown in FIG. 13 includes power consumed by the power amplifier 11, the bias current detecting unit 13, and the memory unit 15. In this case here, the conditions are that: the frequency is 824 MHz; the signal is a UMTS (based on HSDPA) modulated signal; the reference voltage VREF of 2.9 V is applied; the bias voltage VDC of 2.9 V is applied; and the input power of the power amplifier 11 is adjusted so as to be 26 dBm when detected by the output power detecting unit 12. More specifically, the gain of the RFIC 16 is adjusted here. Moreover, as a condition in changes in the load impedances of the output power detecting unit 12 and the power amplifier 11, the VSWR range is from 1:1 to 4:1. To be more specific, the load VSWR range of the output power detecting unit 12 is from 1:1 to 4:1.

As shown in FIG. 13, when the load VSWR is 1:1, power consumption by the radio frequency power amplifier 10 in the present embodiment is constant. However, when the load VSWR is 2:1, 3:1, and 4:1, power consumptions drastically change at −90 deg and +110 deg. This is because the collector voltage VCC is changed in these phases, according to the result of the comparison between the bias current detected by the bias current detecting unit 13 and the bias-current reference value IDCREF.

It should be noted here that the power consumption characteristic of the radio frequency power amplifier that uses an isolator is also shown by a long dashed line indicated as “Using isolator” in FIG. 13, for the purpose of comparison.

When an isolator is used, the power consumption characteristic is calculated as follows.

Here, the isolator is inserted into the output of the output power detecting unit 12. Since the insertion loss caused by the isolator is about 0.5 DB, the output power at the isolator output terminal is set to 26.5 dBm. The configuration of the radio frequency power amplifier with the isolator is almost identical to that of the radio frequency power amplifier 10 in the first embodiment according to the present invention, except that the bias current detecting unit 13 and the memory unit 15 are not provided. Also note that the bias conditions (which are the collector voltage VCC of 3.5 V, the reference voltage VREF of 2.9 V, and the bias voltage VDC of 2.9 V) are equivalent to those in the case of the radio frequency power amplifier 10 in the first embodiment.

When the output power of the power amplifier 11 is increased from 26 dBm to 26.5 dBm, the collector current is increased by about 10 mA. On this account, the power consumption by the power amplifier 11 when the isolator is used is expressed by the following expression.

Power consumption by the power amplifier 11=3.5*310 mA=1085 mW Expression 5

Next, power consumption by the power amplifier 11 when the isolator is used, as calculated above, is compared with power consumption in the case where the load VSWR range is from 1:1 to 4:1 as the load impedance of the radio frequency power amplifier 10 in the first embodiment.

As shown in FIG. 13, power consumption by the radio frequency power amplifier 10 when the load VSWR is 1:1 can be reduced by at least 30 mW as compared with the case where the isolator is used.

Also, power consumption by the radio frequency power amplifier 10 when the load VSWR is 2:1 is higher than the case where the isolator is used, within about 5 degrees from +110 deg to +115 deg in the load impedance phase. However, in almost all the other phases (from +115 deg to +180 deg and from −180 deg to +110 deg), low power consumption can be achieved.

Moreover, power consumption by the radio frequency power amplifier 10 in the first embodiment when the load VSWR is 3:1 is higher than the case where the isolator is used, within about 130 degrees in the load impedance phase, that is, from −50 deg to +60 deg, from +110 deg to +125 deg, and from −95 deg to −90 deg. However, in the other phases (i.e., 230 degrees), low power consumption can be achieved.

Furthermore, power consumption by the radio frequency power amplifier 10 in the first embodiment when the load VSWR is 4:1 is higher than the case where the isolator is used, within about 142 degrees in the load impedance phase, that is, from −55 deg to +70 deg, from +110 deg to +122 deg, and from −95 deg to −90 deg. However, in the other phases (i.e., 218 degrees), low power consumption can be achieved.

Accordingly, the radio frequency power amplifier 10 in the first embodiment can be compared favorably with the radio frequency power amplifier with the isolator, and can reduce power consumption.

In the case of reducing power consumption under the impedance condition which is relatively frequently used (the antenna load VSWR range is generally from 1:1 to 4:1), the control setting as described is adequate. However, for the phases in which the power consumption is higher than that in the case where the isolator is used, a reference value of the bias current IDC for VSWR=1:1 (the load impedance is 50Ω) may be further provided so as to control the collector voltage more minutely. As a result of this, power consumption can be lower than that in the case where the isolator is used and, therefore, a favorable high frequency characteristic can be achieved in all the existable load impedance phases.

As described thus far, the radio frequency power amplifier 10 in the first embodiment includes: the power amplifier 11 which amplifies a radio frequency signal; the voltage supplying unit 14 which supplies the collector voltage VCC to the power amplifier 11; the current supplying unit which supplies the bias current IDC to the power amplifier 11; and the bias current detecting unit 13 which detects the bias current IDC. Here, the voltage supplying unit 14 sets the collector voltage at: VCC_up when the detected bias current IDC is lower than the bias-current reference value IDCREF; VCC_typ when the detected bias current IDC is substantially equal to the reference value IDCREF; and VCC_down lower than VCC_up when the detected bias current IDC is higher than the reference value IDCREF.

With this configuration, the radio frequency power amplifier 10 in the present embodiment can achieve a favorable high frequency characteristic without using an isolator and can reduce power consumption at the same time.

### Modification of First Embodiment

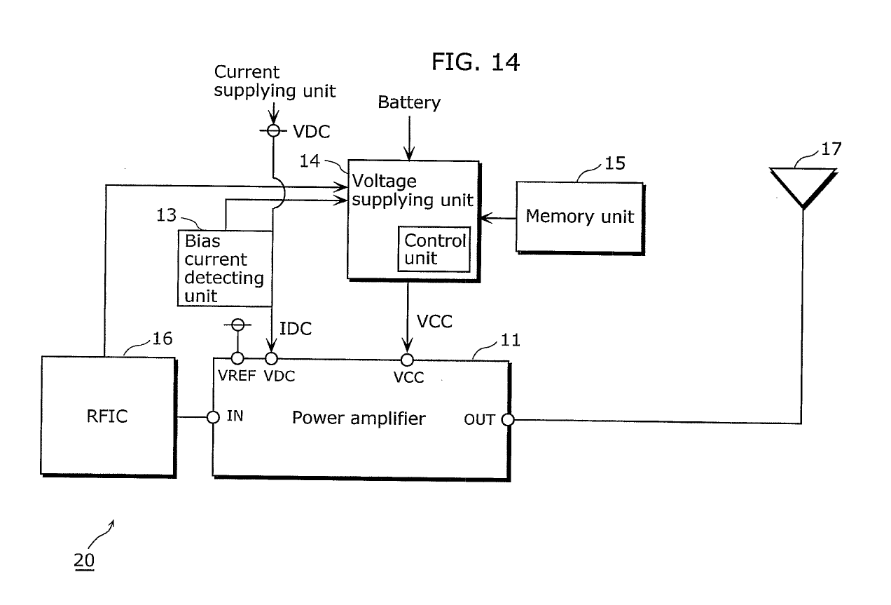

FIG. 14 is a block diagram showing a configuration of a radio frequency power amplifier in the present modification.

A radio frequency power amplifier 20 in the present modification is almost identical to the radio frequency power amplifier 10 in the first embodiment, and is different in that the output power detecting unit 12 for detecting the output power of the power amplifier 11 is not provided.

The output power of the power amplifier 11 is determined by the gain of the RFIC 16 and the amplification gain of the power amplifier 11. On account of this, the RFIC 16 can obtain the power of the radio frequency signal provided by the power amplifier 11, from the gain of the RFIC 16 and the amplification gain of the power amplifier 11. More specifically, the RFIC 16 in the present modification corresponds to the obtaining unit according to the present invention, and estimates the output power of the power amplifier 11 from the power of the radio frequency signal received by the power amplifier 11 and the amplification gain of the power amplifier 11.

In the radio frequency power amplifier 10 of the first embodiment, the output power detecting unit 12 connected to the power amplifier 11 is used for detecting the output power of the power amplifier 11. On the other hand, in the radio frequency power amplifier 20 of the present modification, the RFIC 16 connected to the power amplifier 11 estimates the output power of the power amplifier 11 in place of the output power detecting unit 12 of the first embodiment. Thus, the radio frequency power amplifier 20 in the present modification can achieve cost reduction and miniaturization, as compared to the radio frequency power amplifier 10 in the first embodiment.

### Second Embodiment

A radio frequency power amplifier in the present embodiment is different from the radio frequency power amplifier 10 in the first embodiment in that the present radio frequency power amplifier is a multiband amplifier.

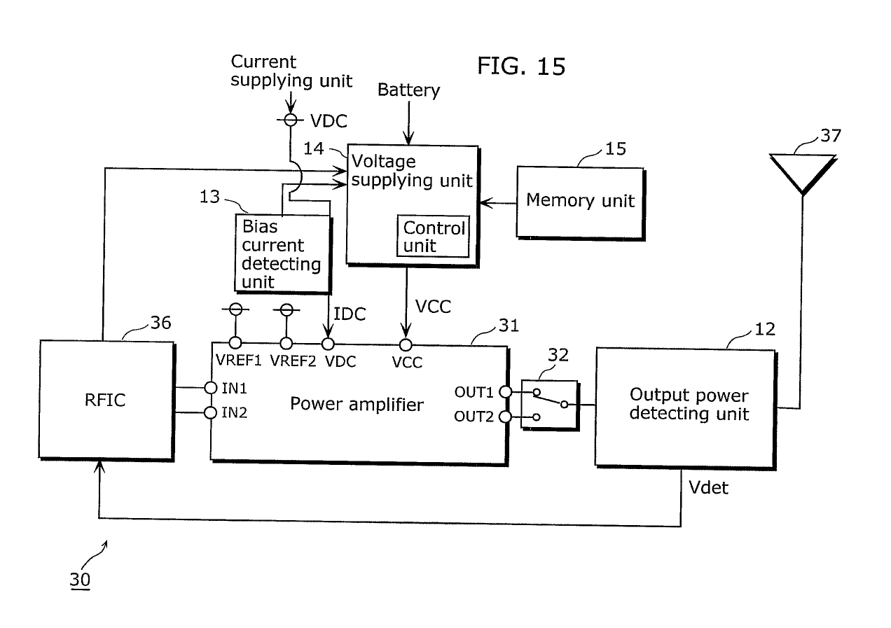

FIG. 15 is a block diagram showing a configuration of the radio frequency power amplifier in the second embodiment.

A radio frequency power amplifier 30 shown in FIG. 15 is different from the radio frequency power amplifier 10 shown in FIG. 1 in the first embodiment as follows. The radio frequency power amplifier 30 includes: a switch 32; a power amplifier 31 in place of the power amplifier 11; an RFIC 36 in place of the RFIC 16; and a multiband antenna 37 supporting multiple bands in place of the antenna 17.

The RFIC 36 supports multiple bands, such as UMTS Band-I and UMTS Band-V, and provides a separate radio frequency signal for each band to the power amplifier 31.

The power amplifier 31 has two input terminals IN1 and IN2 and two output terminals OUT1 and OUT2 corresponding to the multiple bands, and amplifies the radio frequency signal received from the RFIC 36.

The switch 32 is inserted between the power amplifier 31 and the output current detecting unit 12. Depending on the band used for communication, the switch 32 connects the output terminal OUT1 of the power amplifier 31 to the output current detecting unit 12, or connects the output terminal OUT2 of the power amplifier 31 to the output current detecting unit 12.

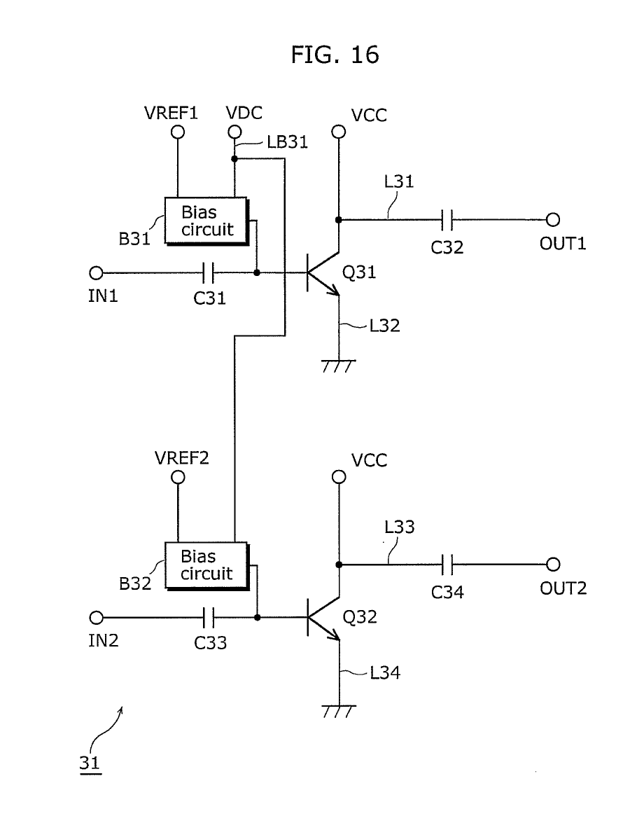

FIG. 16 is a schematic circuit diagram showing a specific configuration of the power amplifier 31.

In the power amplifier 31 shown in FIG. 16, the power amplifier 11 shown in FIG. 3 is arranged for each of the bands so that the power amplifiers 11 are connected in parallel. To be more specific, the power amplifier 31 has capacities C31 and C32, a power amplifying transistor Q31, and a bias circuit B31 for a first band (also referred to as the first frequency band). Also, the power amplifier 31 has capacities C33 and C34, a power amplifying transistor Q32, and a bias circuit B32 for a second band (also referred to as the second frequency band) which is different from the first band. Moreover, the power amplifier 31 has a bias line LB31 which is connected to bases of the power amplifying transistors Q31 and Q32 via the bias voltage applying terminal VDC and the bias circuits B31 and B32.

As described, the power amplifier 31 of the radio frequency power amplifier 30 in the present embodiment includes: the power amplifying transistor Q31 which amplifies a radio frequency signal of the first frequency band; the power amplifying transistor Q32 which amplifies a radio frequency signal of the second frequency band different from the first frequency band; and the bias line LB31 which is provided in common to the power amplifying transistors Q31 and Q32 so that bias current is supplied to each of the power amplifying transistors Q31 and Q32. It should be noted that the power amplifying transistors Q31 and Q32 correspond to the first and second amplifying elements, respectively, according to the present invention.

Accordingly, the radio frequency power amplifier 30 in the present embodiment can support the multiple bands and also detect the bias currents using the single bias current detecting unit 13, thereby achieving miniaturization.

The power amplifier 31 has: a first line L31 connected to a collector of the power amplifying transistor Q31 and used for transmitting the radio frequency signal amplified by the power amplifying transistor Q31; a second line L32 connected to an emitter of the power amplifying transistor Q31; a third line L33 connected to a collector of the power amplifying transistor Q32 and used for transmitting the radio frequency signal amplified by the power amplifying transistor Q32; and a fourth line L34 connected to an emitter of the power amplifying transistor Q32. The bias line LB31 is arranged so as not to overlap with any of the first to fourth lines L31 to L34.

This configuration can reduce the influence of signal leakage from an active power amplifying transistor to an inactive power amplifying transistor via the first to fourth lines L31 to L34 and the bias line LB31. To be more specific, in the multiband power amplifier 31, while one of the power amplifying transistor Q31 and Q32 is active, the other one is inactive. When the radio frequency signal having been amplified by the active power amplifying transistor is leaked out to the inactive power amplifying transistor via the bias line LB31, a malfunction or a reduction in transmission output occurs as a result. By arranging the bias line LB31 as described above, a leakage of the radio frequency signal via the bias line LB31 is prevented. Thus, a malfunction or a reduction in transmission output is prevented from occurring to the power amplifier 31.

### Third Embodiment

A radio frequency power amplifier in the present embodiment is different from the radio frequency power amplifier 10 of the first embodiment in that power amplifying transistors of a power amplifier are arranged in multiple stages.

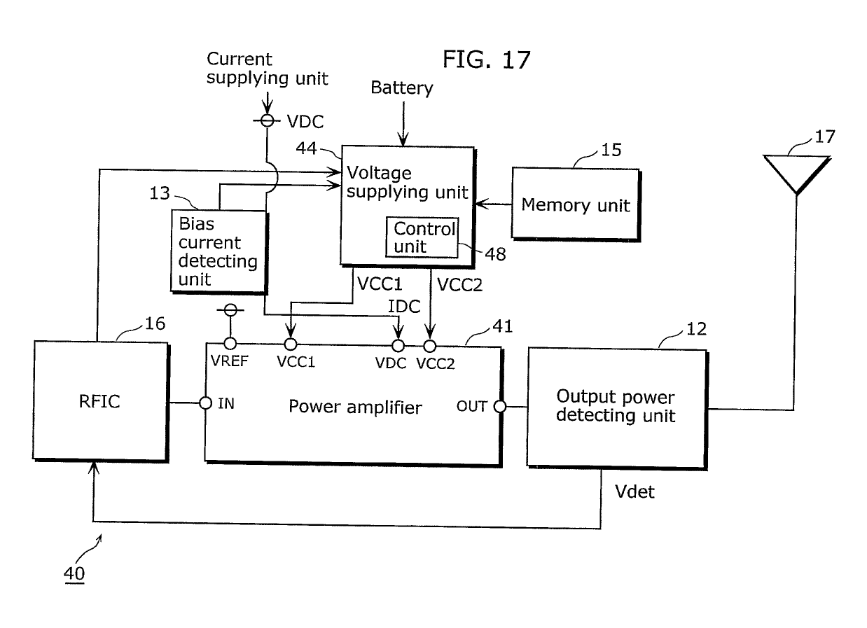

FIG. 17 is a block diagram showing a configuration of a radio frequency power amplifier in the third embodiment. A radio frequency power amplifier 40 shown in FIG. 17 is different from the radio frequency power amplifier 10 shown in FIG. 1 as follows. The radio frequency power amplifier 40 includes: a power amplifier 41 in place of the power amplifier 11; and a voltage supplying unit 44 in place of the voltage supplying unit 14.

The power amplifier 41 is different from the power amplifier 11 in that the power amplifier 41 has two power amplifying transistors connected in multiple stages and two collector voltage applying terminals VCC1 and VCC2. The collector voltage applying terminal VCC1 supplies a collector voltage to the power amplifying transistor of a former stage, and the collector voltage applying terminal VCC2 supplies a collector voltage to the power amplifying transistor of a latter stage.

The voltage supplying unit 44 has a control unit 48, in place of the control unit 18 in the voltage supplying unit 14 of the first embodiment. The control unit 48 controls the collector voltages VCC1 and VCC2 of the respective power amplifying transistors of the former and latter stages, according to the output power Vdet detected by the output power detecting unit 12 and the bias current IDC detected by the bias current detecting unit 13.

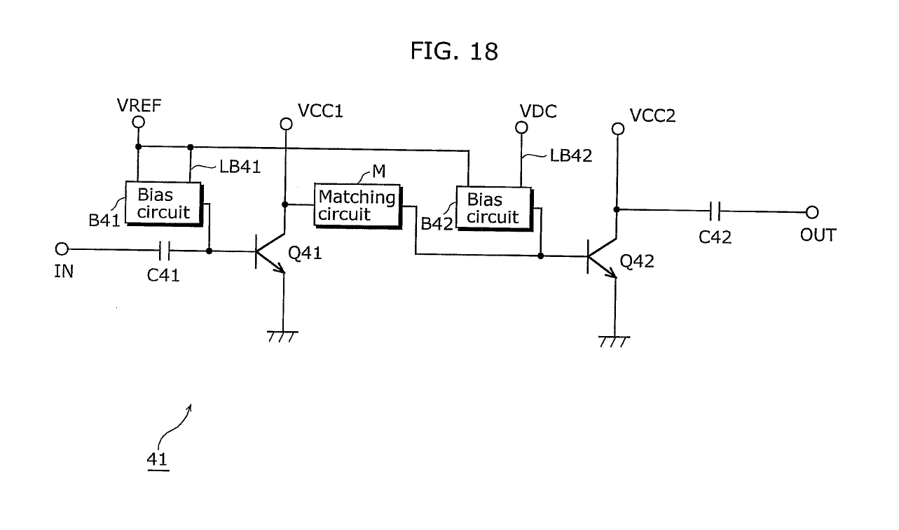

FIG. 18 is a schematic circuit diagram showing a specific configuration of the power amplifier 41.

The power amplifier 41 shown in FIG. 18 is different from the power amplifier 11 shown in FIG. 3 as follows. The power amplifier 41 has: two power amplifying transistors Q41 and Q42 connected in multiple stages; and a matching circuit M between a collector, i.e., an output terminal, of the power amplifying transistor Q41 of the former stage and a base, i.e., an input terminal, of the power amplifying transistor Q42 of the latter stage. The matching circuit M performs impedance matching between the power amplifying transistor Q41 of the former stage and the power amplifying transistor Q42 of the latter stage. Moreover, the power amplifier 41 has a bias circuit B41 corresponding to the power amplifying transistor Q41 of the former stage and a bias circuit B42 corresponding to the power amplifying transistor Q42 in the latter stage. It should be noted that capacities C41 and C42 are identical to the capacities C1 and C2 and, therefore, the detailed explanation about them is omitted here.

Furthermore, the power amplifier 41 has two bias lines LB 41 and LB42 for supplying bias currents to the two power amplifying transistors Q41 and Q42, respectively. The bias line LB41 is connected to the reference voltage applying terminal VREF and used for supplying the bias current to the base of the power amplifying transistor Q41. The bias line LB42 is connected to the bias voltage applying terminal VDC and is used for supplying the bias current to the base of the power amplifying transistor Q42.

In this way, the bias current detecting unit 13 in the present embodiment detects the bias current IDC supplied to the bias line LB42 that corresponds to the power amplifying transistor Q42 of the latter stage.

As described, the power amplifier 41 of the radio frequency power amplifier 40 in the present embodiment has: the two power amplifying transistors Q41 and Q42 connected in the multiple stages; and the two bias lines LB41 and LB42 for supplying the bias currents to the two power amplifying transistors Q41 and Q42, respectively. The bias current detecting unit 13 detects the bias current IDC supplied to the bias line LB42 corresponding to the power amplifying transistor Q42 of the latter stage.

Accordingly, without being influenced by the changes in the bias current of the power amplifying transistor Q41 of the former stage in which the phase is shifted by the matching circuit M, the bias current detecting unit 13 is influenced only by the changes in the bias current of the power amplifying transistor Q42 of the latter stage. In other words, the influence of the bias current of the power amplifying transistor Q41 of the former stage can be excluded from the bias current IDC detected by the bias current detecting unit 13. As a result, the bias current detecting unit 13 can precisely detect the bias current of the power amplifying transistor Q42 of the latter stage, thereby improving the ACLR5 MHz characteristic of the radio frequency power amplifier 40.

To be more specific, the ACLR5 MHx characteristic of the power amplifier including the multistage-connected power amplifying transistors is dominantly influenced by the power amplifying transistor of the latter stage. On this account, the bias current detecting unit 13 detects the bias current IDC of the power amplifying transistor Q42 of the latter stage with a high degree of precision while excluding the influence of the bias current of the power amplifying transistor Q41 of the former stage. Then, according to the bias current detected with a high degree of precision, the collector voltages VCC1 and VCC2 are controlled. This accordingly results in an improvement in the ACLR5 MHx characteristic.

### Fourth Embodiment

A radio frequency power amplifier in the present embodiment is identical to the radio frequency power amplifier in the third embodiment in that a power amplifier has power amplifying transistors connected in multiple stages. However, the radio frequency power amplifier in the present embodiment is different in that the bias current is detected for each of the power amplifying transistors of the stages.

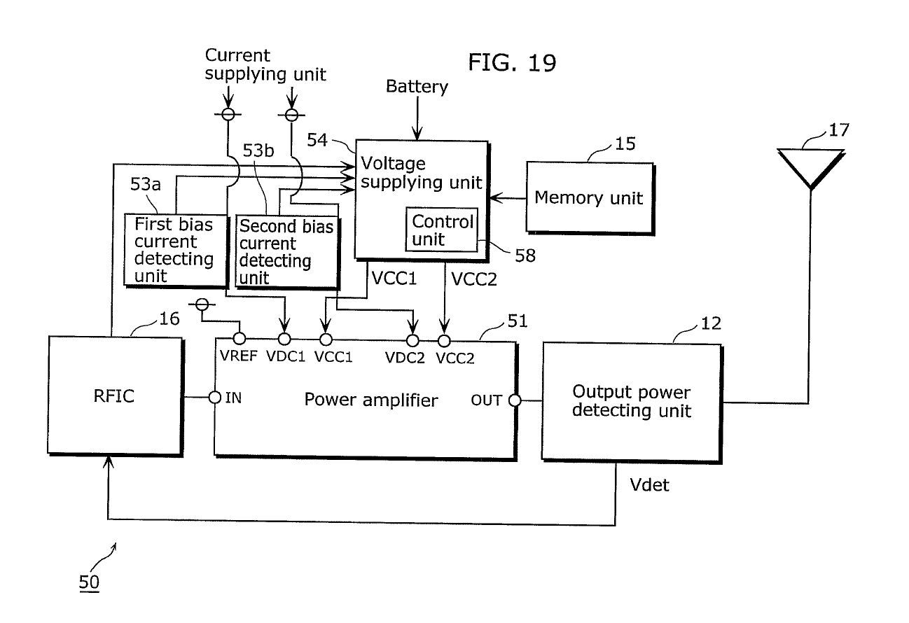

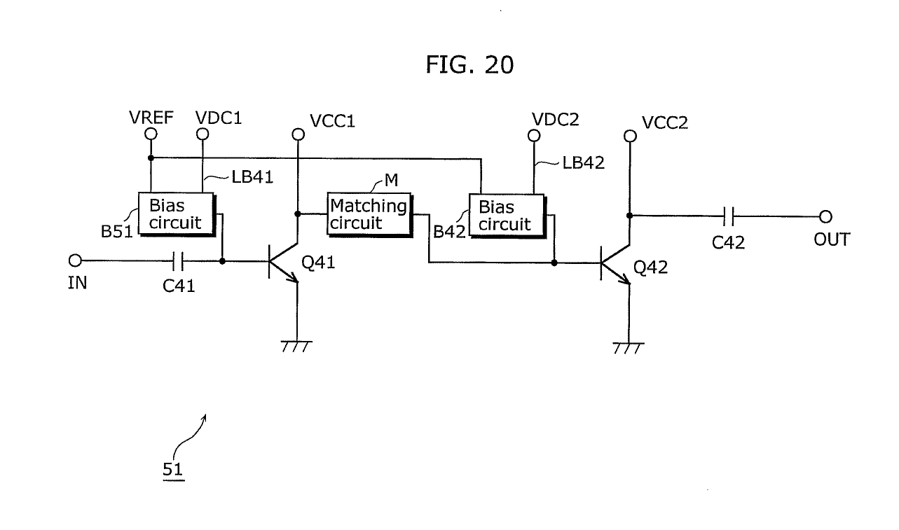

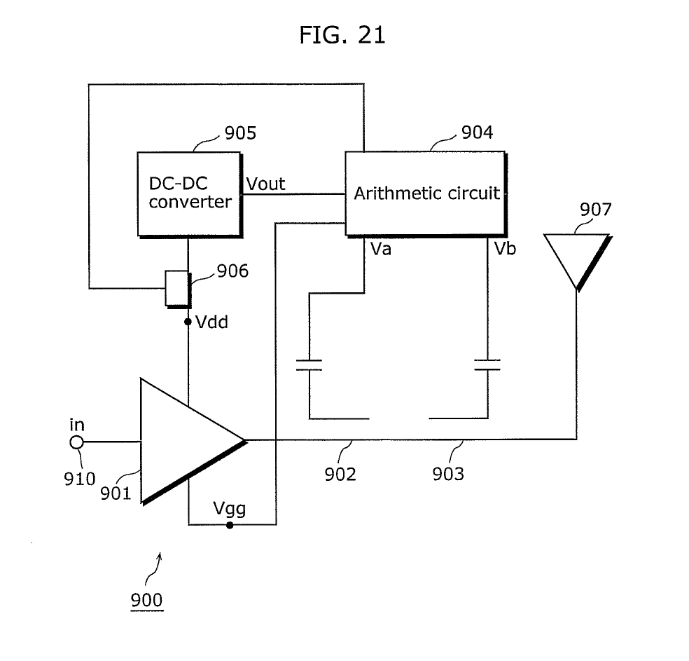

FIG. 19 is a block diagram showing a configuration of the radio frequency power amplifier in the present embodiment. FIG. 20 is a schematic circuit diagram showing a specific configuration of the power amplifier included in the radio frequency power amplifier in the present embodiment.

A radio frequency power amplifier 50 shown in FIG. 19 is different from the radio frequency power amplifier 40 shown in FIG. 17 in the third embodiment as follows. The radio frequency power amplifier 50 includes: a power amplifier 51 in place of the power amplifier 41; a first bias current detecting unit 53a and a second bias current detecting unit 53b in place of the bias current detecting unit 13; and a voltage supplying unit 54 in place of the voltage supplying unit 44.

The power amplifier 51 is different from the power amplifier 41 in that the power amplifier 51 additionally has: a bias voltage applying terminal VDC1 for supplying the bias current of the power amplifying transistor Q41 of the former stage; and a bias voltage applying terminal VDC2 for supplying the bias current of the power amplifying transistor Q42 of the latter stage. Also, in the power amplifier 51, a bias circuit B51 corresponding to the power amplifying transistor Q41 of the former stage is connected to the bias voltage applying terminal VDC1. It should be noted that the bias voltage applying terminal VDC2 shown in FIGS. 19 and 20 is identical to the bias voltage applying terminal VDC shown in FIGS. 17 and 18.

The first bias current detecting unit 53a detects the bias current of the power amplifying transistor Q41 of the former stage. The second bias current detecting unit 53b detects the bias current of the power amplifying transistor Q42 of the latter stage.

The voltage supplying unit 54 has a control unit 58, in place of the control unit 48 in the voltage supplying unit 44. The control unit 58 controls the collector voltages VCC1 and VCC2 of the respective power amplifying transistors Q41 and Q42 of the former and latter stages, according to the bias current of the power amplifying transistor Q41 of the former stage detected by the first bias current detecting unit 53a and the bias current of the power amplifying transistor Q42 of the latter stage detected by the second bias current detecting unit 53b, respectively.

As described, the first bias current detecting unit 53a and the second bias current detecting unit 53b included in the radio frequency power amplifier 50 in the present embodiment detect the respective bias currents supplied to the two bias lines LB41 and LB42, in association with the corresponding power amplifying transistors Q41 and Q42, respectively. To be more specific, the first bias current detecting unit 53a detects the bias current of the power amplifying transistor Q41, and the second bias current detecting unit 53b detects the bias current of the power amplifying transistor Q42.

With this, even in the event of a phase shift between the power amplifying transistors Q41 and Q42 of the former and latter stages, or degradation in the ACLR5 MHz characteristic of the power amplifying transistor Q1 of the former stage, the collector voltages VCC1 and VCC2 can be controlled with consideration given to the influence caused by the event.

### Modification of Fourth Embodiment

A radio frequency power amplifier in the present modification is identical to the radio frequency power amplifier in the fourth embodiment, except that the control unit further controls the collector voltages VCC1 and VCC2 according to a difference between the bias currents of the power amplifying transistors Q41 and Q42 of the former and latter stages.

As the load impedance becomes substantially different from VSWR=1:1 (50Ω), the output signals of the power amplifying transistors Q41 and Q42 are more destructed due to the backward reflected radio frequency signal from the antennal 17 to the power amplifier 51. The phase in which such destruction is to occur includes a current falling edge in the current phase transition. For this reason, in order to prevent the output signals of the power amplifying transistors Q41 and Q42 from being destructed, it is necessary to determine the phase in which the current rises in the current phase transition. To be more specific, as seen from FIGS. 5A, 5B, 6A, and 6B, it is necessary to determine the phase in which the bias current decreases with respect to the phase change of the load VSWR. Once the phase is determined, resistance properties to destruction can be improved by setting the collector voltages VCC1 and VCC2 at high values.

Here, when the bias current of only the power amplifying transistor Q42 of the latter stage is to be detected, phases in which the current rises and falls are both detected. Thus, destruction cannot be prevented. To address this, on the basis of a phase shift between the bias currents of the power amplifying transistors Q41 and Q42 of the former and latter stages, a phase in which the bias current rises is determined using an interstage matching circuit. In the determined phase, the collector voltages VCC1 and VCC2 are accordingly increased. This can prevent the ACLR5 MHz characteristic from degrading, and also prevent the output signals of the power amplifying transistors Q41 and Q42 from being destructed.

In this way, the radio frequency power amplifier in the present modification controls the collector voltages VCC1 and VCC2 according to the difference between the bias currents of the power amplifying transistors Q41 and Q42 of the former and latter stages, so that the output signals of the power amplifying transistors Q41 and Q42 are prevented from being destructed. It should be noted that, in order to prevent the output signals of the power amplifying transistors Q41 and Q42 from being destructed, a high voltage (equal to or higher than VCC_up, for example) may be set as the collector voltages VCC1 and VCC2.

As described thus far, the radio frequency power amplifier according to the present invention has been explained based on the first to fourth embodiments and the modifications. However, the present invention is not limited to the above embodiments and modifications. Various improvements and modifications made without departing from the teachings of the present invention are included in the scope of the present invention.

For example, in the above description, the control unit 18 sets the collector voltage at: VCC_up when the bias current IDC detected by the bias current detecting unit 13 is lower than the bias-current reference value IDCREF; VCC_typ when the bias current IDC detected by the bias current detecting unit 13 is substantially equal to the bias-current reference value IDCREF; and VCC_down when the bias current IDC detected by the bias current detecting unit 13 is higher than the bias-current reference value IDCREF. However, the control unit 18 may control the collector voltage, on the basis of two values instead of the above three values.

More specifically, the control unit may set the collector voltage at: VCC_up when the bias current IDC detected by the bias current detecting unit 13 is equal to or lower than the bias-current reference value IDCREF; and VCC_down when the bias current IDC detected by the bias current detecting unit 13 is higher than the bias-current reference value IDCREF.

In the above description, the control unit 18 uses the bias-current reference value IDCREF as the threshold, corresponding to the output power. To be more specific, a plurality of thresholds are set corresponding to a plurality of output power values. However, a single threshold may be set corresponding to a plurality of output power values. Or, a single threshold may be set for each predetermined output power range.

In the second embodiment, the radio frequency power amplifier 30 supports two bands. However, the radio frequency power amplifier may support three or more bands. In this case, each of the bias lines for supplying the bias currents to the plurality of multiband power amplifying transistors included in the power amplifier needs to overlap with both of lines connected to a collector and an emitter of the corresponding individual power amplifying transistor.

In the third and fourth embodiments, two power amplifying transistors are connected in multiple stages. However, three or more power amplifying transistors may be connected in multiple stages.

The present invention can be implemented not only as the radio frequency power amplifier described above, but also as a wireless communication device having such a radio frequency power amplifier.

Although only some exemplary embodiments of this invention have been described in detail above, those skilled in the art will readily appreciate that many modifications are possible in the exemplary embodiments without materially departing from the novel teachings and advantages of this invention. Accordingly, all such modifications are intended to be included within the scope of this invention.

### INDUSTRIAL APPLICABILITY

The radio frequency power amplifier and the wireless communication device having the radio frequency power amplifier according to the present invention are suited for use as mobile communication terminals, such as a mobile phone terminal having no isolator.

What is claimed is:

1. A radio frequency power amplifier comprising:
an amplifying unit configured to amplify a radio frequency signal;
a voltage supplying unit configured to supply a power supply voltage to said amplifying unit;
a current supplying unit configured to supply a bias current to said amplifying unit; and
a detecting unit configured to detect the bias current,
wherein said voltage supplying unit includes a control unit configured to set the power supply voltage at: a first voltage when a value of the detected bias current is equal to or lower than a threshold; and a second voltage lower than the first voltage when the value of the detected bias current is higher than the threshold.

2. The radio frequency power amplifier according to claim 1,
wherein the threshold indicates a bias-current reference value in association with a value of an output power of said amplifying unit, the bias-current reference value corresponding to an ideal output load on said radio frequency power amplifier.

3. The radio frequency power amplifier according to claim 2 further comprising:
a memory which stores a plurality of bias-current reference values in association with a plurality of values of the output power, the bias-current reference values corresponding to the ideal output load on said radio frequency power amplifier; and
an obtaining unit configured to obtain the value of the output power of said amplifying unit,
wherein said control unit is configured to compare the bias-current reference value stored in said memory in association with the obtained value of the output power of said amplifying unit and the value of the bias current detected by said detecting unit, and to set the power supply voltage at: the first voltage when the value of the bias current detected by said detecting unit is equal to or lower than the bias-current reference value stored in said memory; and the second voltage when the value of the bias current detected by said detecting unit is higher than the bias-current reference value stored in said memory.

4. The radio frequency power amplifier according to claim 1,
wherein the second voltage is a voltage for causing an adjacent channel leakage ratio of said radio frequency power amplifier to be lower than a predetermined value when the value of the detected bias current is higher than the threshold.

5. The radio frequency power amplifier according to claim 1,
wherein the first voltage is a voltage for causing the adjacent channel leakage ratio of said radio frequency power amplifier to be lower than the predetermined value regardless of the value of the detected bias current.

6. The radio frequency power amplifier according to claim 1,
wherein, when the power supply voltage is set at the first voltage and the value of the detected bias current becomes higher than the threshold, said control unit is configured to change the power supply voltage from the first voltage to the second voltage.

7. The radio frequency power amplifier according to claim 1,
wherein, when the power supply voltage is set at the second voltage and the value of the detected bias current becomes equal to or lower than the threshold, said control unit is configured to change the power supply voltage from the second voltage to the first voltage.

8. The radio frequency power amplifier according to claim 1,
wherein said control unit is further configured to control the power supply voltage according to the output power of said amplifying unit.

9. The radio frequency power amplifier according to claim 8,
wherein, when the output power of said amplifying unit is higher than a predetermined power, said control unit is configured to set a first upper-limit voltage as the first voltage, and
when the output power of said amplifying unit is equal to or lower than the predetermined power, said control unit is configured to set, as the first voltage, a second upper-limit voltage lower than the first upper-limit voltage.

10. The radio frequency power amplifier according to claim 9,
wherein, when the output power of said amplifying unit is higher than the predetermined power, said control unit is configured to set a voltage equal to or higher than the second upper-limit voltage as the second voltage.

11. The radio frequency power amplifier according to claim 3,
wherein said obtaining unit is connected to said amplifying unit and configured to detect the output power of said amplifying unit.

12. The radio frequency power amplifier according to claim 3,
wherein said obtaining unit is configured to estimate the output power of said amplifying unit, from a power of the radio frequency signal received by said power amplifying unit and an amplification gain of said power amplifying unit.

13. The radio frequency power amplifier according to claim 1,
wherein said amplifying unit has:
a first amplifying element which amplifies the radio frequency signal in a first frequency band;
a second amplifying element which amplifies the radio frequency signal in a second frequency band different from the first frequency band; and
a bias line provided in common to said first amplifying element and said second amplifying element so that the bias current is supplied to each of said first amplifying element and said second amplifying element.

14. The radio frequency power amplifier according to claim 13,
wherein each of said first amplifying element and said second amplifying element is a transistor,
said amplifying unit further has:
a first line connected to a collector of said first amplifying element and used for transmitting the radio frequency signal amplified by said first amplifying element;
a second line connected to an emitter of said first amplifying element;
a third line connected to a collector of said second amplifying element and used for transmitting the radio frequency signal amplified by said second amplifying element; and
a fourth line connected to an emitter of said second amplifying element, and
said bias line is arranged so as not to overlap with any of said first to fourth lines.

15. The radio frequency power amplifier according to claim 1,
wherein said amplifying unit has:
an m number of amplifying elements connected in multiple stages, m being an integer of at least 2; and
an m number of bias lines for supplying bias currents to said m number of amplifying elements, respectively, and
said detecting unit is configured to detect the bias current supplied to at least one of said m number of bias lines.

16. The radio frequency power amplifier according to claim 15,
wherein said detecting unit is configured to detect the bias current supplied to a bias line corresponding to an amplifying element of a final stage out of the multiple stages.

17. The radio frequency power amplifier according to claim 15,
wherein said detecting unit is configured to detect the bias currents supplied to said m number of bias lines, in association with said m number of amplifying elements, respectively.

18. The radio frequency power amplifier according to claim 17,
wherein said control unit is further configured to control the power supply voltage, according to a difference between: the bias current supplied to an amplifying element, out of said m number of amplifying elements, of an i-th stage where 1≦i≦m-1; and the bias current supplied to an amplifying element, out of said m number of amplifying elements, of a j-th stage where i<j and 2≦j≦m.

19. The radio frequency power amplifier according to claim 1, further comprising:
a current control transistor for controlling the bias current; and
a temperature compensation circuit for performing temperature compensation on said current control transistor and said amplifying unit.

20. A wireless communication device comprising
the radio frequency power amplifier according to claim 1.
